(19) United States
(12) Patent Application Publication
(10) Pub. No.: US 2023/0139917 A1
(43) Pub. Date: May 4, 2023

(54) SELECTIVE DEPOSITION USING THERMAL AND PLASMA-ENHANCED PROCESS

(71) Applicant: ASM IP Holding, B.V., Almere (NL)

(72) Inventors: Eva Tois, Espoo (FI); Viraj Madhiwala, Helsinki (FI); Daniele Chiappe, Espoo (FI); Marko Tuominen, Helsinki (FI); Shaoren Deng, Ghent (BE); Anirudhan Chandrasekaran, Scottsdale, AZ (US); YongGuy Han, Seoul (KR); Michael Givens, Oud-Heverlee (BE); Andrea Illiberi, Leuven (BE); Vincent Vandalon, Heverlee (BE)

(21) Appl. No.: 18/050,128

(22) Filed: Oct. 27, 2022

Related U.S. Application Data
(60) Provisional application No. 63/273,286, filed on Oct. 29, 2021.

(51) Int. Cl. C23C 16/455

(52) U.S. Cl. CPC C23C 16/45534; C23C 16/4554; C23C 16/45529

(57) ABSTRACT

Methods and vapor deposition assemblies of selectively depositing dielectric material on a first surface of a substrate relative to a second surface of the substrate by a cyclic deposition process are disclosed. The methods comprise providing a substrate into a reaction chamber, performing a thermal deposition subcycle performing a thermal deposition subcycle to selectively deposit a first material on the first surface, performing a plasma deposition subcycle to selectively deposit a second material on the first surface; wherein at least one of the first material and the second material comprises silicon and oxygen.

### FIELD

The present disclosure relates to methods and apparatuses for the manufacture of semiconductor devices. More particularly, the disclosure relates to methods and apparatuses for selectively depositing dielectric material on a substrate, and layers comprising dielectric material.

### BACKGROUND

Semiconductor device fabrication processes generally use advanced deposition methods. Patterning is conventionally used in depositing different materials on semiconductor substrates. Selective deposition, which is receiving increasing interest among semiconductor manufacturers, could enable a decrease in steps needed for conventional patterning, reducing the cost of processing. Selective deposition could also allow enhanced scaling in narrow structures. Various alternatives for bringing about selective deposition have been proposed, and additional improvements are needed to expand the use of selective deposition in industrial-scale device manufacturing.

Silicon oxide, sometimes containing additional elements and/or silicates is used in many different applications, and it is one of the most widely used materials in semiconductor industry. Therefore, improvements in the selective deposition of silicon oxide are highly sought after and may have a large impact in making semiconductor device manufacturing faster and more cost-effective. Both thermal and plasma-based processes for depositing silicon oxide -based materials have their advantages and disadvantages. The two processes often utilize different precursors, and the deposition conditions are generally considered incompatible. A novel deposition process is proposed in the current disclosure that allows taking advantage of the advantages of both thermal and plasma-enhanced processes.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY

This summary may introduce a selection of concepts in a simplified form, which may be described in further detail below. This summary is not intended to necessarily identify key features or essential features of the claimed subject matter, nor is it intended to be used to limit the scope of the claimed subject matter. Various embodiments of the present disclosure relate to methods of selectively depositing dielectric material on a substrate, to a dielectric material layer, to a semiconductor structure and a device, and to deposition assemblies for depositing dielectric material on a substrate.

In an aspect, a method of selectively depositing dielectric material on a first surface of a substrate relative to a second surface of the substrate by a cyclic deposition process is disclosed. The method comprises providing a substrate into a reaction chamber. Thereafter, a thermal deposition subcycle to selectively deposit a first material on the first surface of the substrate and a plasma deposition subcycle to selectively deposit a second material on the first surface are performed. In the method, at least one of the first material and the second material comprises silicon and oxygen.

In some embodiments, the method comprises providing a metal or metalloid catalyst into the reaction chamber in vapor phase before performing a thermal deposition subcycle. In some embodiments, the thermal deposition subcycle comprises providing a metal or metalloid catalyst into the reaction chamber in a vapor phase. In some embodiments, the plasma deposition subcycle comprises providing a metal or metalloid catalyst into the reaction chamber in a vapor phase. In some embodiments, the thermal deposition subcycle and the plasma deposition subcycle comprise providing a metal or metalloid catalyst into the reaction chamber in a vapor phase. Thus, each of the subcycles may contain additional process steps in addition to the ones mentioned above. The additional process steps may allow adjusting the composition and properties of the deposited material. Further, each of the subcycle may comprise repeating at least one of the process steps in the subcycle. For example, the complete subcycle may be performed at least two times before performing the other subcycle.

In some embodiments, the thermal deposition subcycle and the plasma deposition subcycle are performed alternately and sequentially. Thus, the method according to the current disclosure may comprise a master cycle, in which the thermal deposition subcycle and the plasma deposition subcycle alternate. However, a master cycle may comprise additional subcycles, such as a catalyst subcycle comprising providing a metal or metalloid catalyst into the reaction chamber. Such a subcycle may be performed after each deposition subcycle, or once per two or more deposition subcycles—irrespective of the deposition subcycles being thermal deposition subcycles, plasma deposition subcycles, or both. Also, a master cycle may comprise performing one or both of the deposition subcycles more than once. A master cycle may be repeated for a suitable number of times to deposit the desired amount of material on the substrate. In some embodiments, at least one of the thermal deposition subcycle and the plasma deposition subcycle are performed more than once before performing the other subcycle.

The properties of the deposited dielectric material may be influenced by the type of deposition used to deposit the surface-most material layer. Plasma deposition process may, in some embodiments, provide more etch-resistant material, or the material may have other properties that are deemed useful for the application to which the deposited dielectric material is to be used. In some embodiments, the last subcycle of the deposition process is a plasma deposition subcycle.

In some embodiments, the first material is a material comprising silicon and oxygen. In some embodiments, the second material is a material comprising silicon and oxygen. In some embodiments, the first material and the second material are materials comprising silicon and oxygen. Thus, silicon and oxygen-comprising-comprising material, such as silicon oxide layers or metal silicate layers, can be deposited selectively on specific surfaces relative to other surfaces on a substrate by the methods described herein. Either a thermal deposition process or a plasma deposition process, or both may be used to deposit the material comprising silicon and oxygen. In some embodiments, the dielectric material deposited according to the current disclosure comprises substantially only silicon and oxygen, and only minor amounts of other elements, such as metals (e.g. aluminum) or carbon. However, in some embodiments, one of the subcycles may be used to provide additional elements into the dielectric material. For example, a metal or metalloid oxide, such as aluminum oxide, hafnium oxide, lanthanum oxide or boron oxide may be deposited by a thermal deposition subcycle or a plasma deposition subcycle. In some embodiments, one of the first material and the second material comprises a metal or metalloid oxide. In some embodiments, the metal or metalloid is selected from a group consisting of B, Zn, Mg, Mn, La, Hf, Al, Zr, Ti, Sn, Y and Ga. Alternatively or in addition, the material comprising silicon and oxygen may be deposited by a thermal or a plasma process that incorporates an additional element, such as a metal or carbon into the deposited dielectric material.

In some embodiments, the thermal deposition subcycle comprises providing a silicon precursor comprising an alkoxy silane compound into the reaction chamber in a vapor phase and providing an oxygen precursor comprising oxygen and hydrogen into the reaction chamber in vapor phase to form first material comprising silicon and oxygen on the first surface. In some embodiments, the plasma deposition subcycle comprises providing a silicon precursor comprising an alkoxy silane compound into the reaction chamber in a vapor phase; and providing a plasma into the reaction chamber to form a reactive species for forming a second material comprising silicon and oxygen on the first surface.

In some embodiments, the first surface is a dielectric surface. In some embodiments, the dielectric surface comprises silicon. In some embodiments, the second surface comprises a passivation layer. In some embodiments, the passivation layer comprises an organic polymer or a self-assembled monolayer (SAM). In some embodiments, the passivation layer comprises polyimide. In some embodiments, the passivation layer comprises polyamic acid. In some embodiments, the passivation layer comprises polyimide and polyamic acid.

Selective deposition between two surfaces having a chemically distinct composition is sensitive to the reactivity of precursors. On the other hand, especially silicon oxide -based materials are difficult to deposit under mild enough conditions (i.e. low reactivity conditions) to maintain possible surface passivation in functional form. Thus, in methods according to the current disclosure, a metal or metalloid catalyst, i.e. catalyst comprising a metal or a metalloid is used to improve reactivity of a silicon precursor. This may allow the use of mild (i.e. low-reactivity) conditions to maintain passivation on the second surface, while achieving sufficient reactivity of the silicon precursor. In some embodiments, the catalyst is a metal halide, organometallic compound or metalorganic compound. In some embodiments, the catalyst comprises trimethyl aluminum (TMA), dimethylaluminumchloride, aluminum trichloride (AlCl₃), dimethylaluminum isopropoxide (DMAI), tris(tertbutyl)aluminum (TTBA), tris(isopropoxide)aluminum (TIPA), tris(dimethylamino) aluminum (TDMAA) or triethyl aluminum (TEA).

A silicon precursor according to the current disclosure comprise an alkoxy silane. In some embodiments, the alkoxy silane is selected from a group consisting of tetraacetoxysilane, tetramethoxysilane, tetraethoxysilane, trimethoxysilane, triethoxysilane and trimethoxy(3-methoxypropyl)silane.

In the thermal deposition subcycle, an oxygen precursor is used to deposit the dielectric material, such as material comprising silicon and oxygen, metal oxide or a metalloid oxide on the first surface of the substrate. In some embodiments, the oxygen precursor is water. In some embodiments, the oxygen precursor is hydrogen peroxide. In some embodiments, the oxygen precursor is a carboxyl group-comprising-comprising compound. For example, a C1 to C7 carboxylic acid.

In the plasma deposition subcycle, a plasma is used to provide energy for the deposition of the dielectric material. In some embodiments, a plasma used in the plasma deposition subcycle is generated from a noble gas. In some embodiments, the noble gas is selected from a group consisting of helium, neon and argon. In some embodiments, the plasma is additionally generated from an additional element. In some embodiments, the additional element is nitrogen, and the dielectric material further comprises nitrogen. In some embodiments, the dielectric material comprises silicon oxynitride.

In some embodiments, the plasma used in the plasma deposition subcycle is RF plasma, and the plasma power does not exceed 100 W. In some embodiments, plasma ion energy of the plasma used in the plasma deposition subcycle does not exceed 160 eV.

In some embodiments, the selectivity of deposition of the dielectric material on the first surface relative to the second surface is greater than about 50%.

Pressure may affect the deposition process differently depending on whether a plasma process or a thermal process is used. Therefore, in some embodiments, at least two different pressures are used during a deposition cycle. In some embodiments, a first pressure is used during providing the catalyst into the reaction chamber, and a second pressure is used during deposition subcycles. In some embodiments, the first pressure is lower than the second pressure. In some embodiments, the first pressure is lower than about 5 Torr. In some embodiments, a third pressure is used during the thermal deposition subcycle or the plasma deposition subcycle. In some embodiments, all the different pressures used during a deposition process are lower than 25 Torr.

In some embodiments, it is possible to determine a pressure that is suitable for all steps of the deposition process. Using a single pressure may be advantageous from process throughput perspective. In some embodiments, a deposition cycle is performed at a constant pressure. In some embodiments, a deposition cycle is performed at a constant pressure lower than about 20 Torr or lower than about 10 Torr. In some embodiments, a deposition cycle is performed at a constant pressure higher than about 3 Torr. In some embodiments, a deposition cycle is performed one or more pressures between about 3 Torr and about 25 Torr.

In some embodiments, an activation treatment is performed after providing a substrate into a deposition chamber. In some embodiments, the activation treatment comprises providing a catalyst into the reaction chamber in a vapor phase and providing an oxygen precursor into the reaction chamber in a vapor phase. In some embodiments, the catalyst and the oxygen precursor are provided into the reaction chamber cyclically. Alternative means of activating the first surface for depositing dielectric material may be used. In some embodiments, an activation treatment may be performed by providing an oxidant, such as oxygen or hydrogen peroxide, into the reaction chamber. In some embodiments, an activation treatment may be performed by providing plasma, such as hydrogen plasma, oxygen plasma or a combination thereof into the reaction chamber. In some embodiments, an activation treatment may be a treatment by hydrogen gas, or by vapor-phase water.

In another aspect, a vapor deposition assembly for selectively depositing dielectric material on a first surface of a substrate relative to a second surface of the substrate is disclosed. The deposition assembly comprises one or more reaction chambers constructed and arranged to hold the substrate, a precursor injector system constructed and arranged to provide a metal or metalloid catalyst, a silicon precursor and an oxygen precursor into the reaction chamber in a vapor phase and to provide plasma into the reaction chamber. The deposition assembly further comprises a first reactant vessel constructed and arranged to contain the catalyst, a second reactant vessel constructed and arranged to contain the silicon precursor, and a third reactant vessel constructed and arranged to contain the oxygen precursor, a fourth reactant vessel constructed and arranged to contain the plasma precursor and the assembly is constructed and arranged to provide the catalyst, the silicon precursor and the oxygen precursor via the precursor injector system into the reaction chamber, and to generate plasma from the plasma precursor in the reaction chamber for selectively depositing dielectric material on the substrate. In some embodiments, the vapor deposition assembly is further configured and arranged to selectively deposit a passivation layer on the second surface of the substrate.

In some embodiments, the reaction chamber comprises at least two deposition stations for performing different phases of a cyclic deposition process. In some embodiments, at least one of the deposition stations is configured and arranged to contact a substrate with a first silicon precursor comprising an alkoxy silane compound and with an oxygen precursor comprising oxygen and hydrogen to form a first material comprising silicon and oxygen on a substrate. In some embodiments, at least one of the deposition stations is configured and arranged to contact a substrate with a second silicon precursor comprising an alkoxy silane compound and with a plasma to form a second material comprising silicon and oxygen on a substrate.

### BRIEF DESCRIPTION OF DRAWINGS

The accompanying drawings, which are included to provide a further understanding of the disclosure and constitute a part of this specification, illustrate exemplary embodiments, and together with the description help to explain the principles of the disclosure. In the drawings:

FIG. 1 is a schematic presentation of selective deposition according to the current disclosure.

FIG. 2A is a block diagram of exemplary embodiments of a method according to the current disclosure.

FIG. 2B is a block diagram of exemplary embodiments of a method according to the current disclosure.

FIG. 2C is a block diagram of exemplary embodiments of a method according to the current disclosure.

FIG. 3 is a schematic presentation of a deposition assembly according to the current disclosure.

### DETAILED DESCRIPTION

The description of exemplary embodiments of methods, structures, devices and deposition assemblies provided below is merely exemplary and is intended for purposes of illustration only. The following description is not intended to limit the scope of the disclosure or the claims. Moreover, recitation of multiple embodiments having indicated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other. The headings provided herein, if any, are for convenience only and do not necessarily affect the scope or meaning of the claimed invention.

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments. In this disclosure, any defined meanings do not necessarily exclude ordinary and customary meanings in some embodiments.

The dielectric material and layers formed by the methods described herein can be used in a variety of applications in the semiconductor industry. Exemplary embodiments of the disclosure can be used to manufacture electronic devices, such as memory and/or logic circuits. More specifically, the embodiments of the current disclosure may be used to manufacture dielectric layers used, for example, in a wide variety of semiconductor devices, including CMOS, DRAM, flash, and magnetic head applications. Silicon oxide-based materials is also commonly used as a gate dielectric for CMOS, as an electrical isolation layer, and gap filling layer. Ternary materials, such as hafnium or aluminum silicate, or silicon oxycarbide-containing materials have many suitable properties for use in semiconductor applications, and may be deposited by methods according to the current disclosure.

In embodiments of the current disclosure, a method of selectively depositing dielectric material on a first surface of a substrate relative to a second surface of the substrate by a cyclic deposition process is disclosed. The method according to the current disclosure comprises providing a substrate into a reaction chamber.

### Substrate

As used herein, the term “substrate” may refer to any underlying material or materials that may be used to form, or upon which, a device, a circuit, material or a material layer may be formed. A substrate can include a bulk material, such as silicon (such as single-crystal silicon), other Group IV materials, such as germanium, or other semiconductor materials, such as a Group II-VI or Group III-V semiconductor materials. A substrate can include one or more layers overlying the bulk material. The substrate can include various topologies, such as gaps, including recesses, lines, trenches or spaces between elevated portions, such as fins, and the like formed within or on at least a portion of a layer of the substrate. Substrate may include nitrides, for example TiN, oxides, insulating materials, dielectric materials, conductive materials, metals, such as such as tungsten, ruthenium, molybdenum, cobalt, aluminum or copper, or metallic materials, crystalline materials, epitaxial, heteroepitaxial, and/or single crystal materials. In some embodiments of the current disclosure, the substrate comprises silicon. The substrate may comprise other materials, as described above, in addition to silicon. The other materials may form layers. A substate according to the current disclosure comprises two surfaces having different material properties.

### First Surface and Second Surface

According to some aspects of the present disclosure, selective deposition can be used to deposit a dielectric material on a first surface relative to a second surface of the substrate. The two surfaces have different material properties.

In some embodiments, the first surface is a dielectric surface. In some embodiments, the first surface is a high-k dielectric surface. In some embodiments, the first surface is a low-k surface. In some embodiments, the first surface comprises an oxide. In some embodiments, the first surface comprises a nitride. In some embodiments, the first surface comprises silicon. Examples of silicon-comprising dielectric materials include silicon oxide -based materials, including grown or deposited silicon dioxide, doped and/or porous oxides and native oxide on silicon. In some embodiments, the first surface comprises silicon oxide. In some embodiments, the first surface is a silicon oxide surface, such as a native oxide surface, a thermal oxide surface or a chemical oxide surface. In some embodiments, the first surface comprises carbon. In some embodiments, the first surface comprises SiN. In some embodiments, the first surface comprises SiOC. In some embodiments, the first surface is an etch-stop layer. An etch-stop layer may comprise, for example a nitride or an oxide.

In some embodiments the dielectric material comprises a metal oxide. Thus, in some embodiments, a dielectric material is selectively deposited on a first metal oxide surface relative to a second surface. In some embodiments, the first surface comprises aluminum oxide. In some embodiments, the first surface is a high-k surface, such as hafnium oxide-comprising surface, a lanthanum oxide-comprising surface.

In some embodiments, a dielectric material according to the current disclosure is selectively deposited on a first surface comprising a metal oxide relative to another surface. A metal oxide surface may be, for example a tungsten oxide (WOx) surface, hafnium oxide (HfOx) surface, titanium oxide (TiOx) surface, aluminum oxide (AlOx) surface or zirconium oxide (ZrOx) surface. In some embodiments, a metal oxide surface is an oxidized surface of a metallic material. In some embodiments, a metal oxide surface is created by oxidizing at least the surface of a metallic material using oxygen compound, such as compounds comprising O₃, H₂O, H₂O₂, O₂, oxygen atoms, plasma or radicals or mixtures thereof. In some embodiments, a metal oxide surface is a native oxide formed on a metallic material.

In some embodiments, a dielectric material, such as silicon oxide, metal silicate or a combination thereof, is selectively deposited on a first dielectric surface of a substrate relative to a second conductive (e.g., metal or metallic) surface of the substrate. In some embodiments, the first surface comprises hydroxyl (—OH) groups. In some embodiments, the first surface may additionally comprise hydrogen (—H) terminations, such as an HF dipped Si or HF dipped Ge surface. In such embodiments, the surface of interest will be considered to comprise both the —H terminations and the material beneath the —H terminations. In some embodiments the dielectric surface and metal or metallic surface are adjacent to each other. In some embodiments the dielectric material comprises a low-k material.

In some embodiments, a dielectric material such as silicon oxide, metal silicate or a combination thereof, is selectively deposited on a first dielectric surface of a substrate relative to a second, different dielectric surface. In some such embodiments, the dielectric materials have different compositions (e.g., silicon, silicon nitride, carbon, silicon oxide, silicon oxynitride, germanium oxide). In other such embodiments, the dielectric materials can have the same basic composition (e.g., silicon oxide-based layers) but different material properties due to the manner of formation (e.g., thermal oxides, native oxides, deposited oxides). In some embodiments, a passivation blocking agents, such as silylation, is used to improve contrast between two dielectric surfaces before depositing a passivation layer on the first surface.

The term dielectric is used in the description herein for the sake of simplicity in distinguishing from the other surface, namely the metal or metallic surface. It will be understood by those skilled in the art that not all non-conducting surfaces are dielectric surfaces. For example, the metal or metallic surface may comprise an oxidized metal surface that is electrically non-conducting or has a very high resistivity. Selective deposition processes taught herein can deposit on dielectric surfaces with minimal deposition on such adjacent non-conductive metal or metallic surfaces.

For embodiments in which one surface of the substrate comprises a metal, the surface is referred to as a metal surface. In some embodiments, a metal surface consists essentially of, or consists of one or more metals. It may be a metal surface or a metallic surface. In some embodiments the metal or metallic surface may comprise metal, metal oxides, and/or mixtures thereof. In some embodiments the metal or metallic surface may comprise surface oxidation. In some embodiments the metal or metallic material of the metal or metallic surface is electrically conductive with or without surface oxidation. In some embodiments, metal or a metallic surface comprises one or more transition metals. In some embodiments, the metal or metallic surface comprises one or more transition metals from row 4 of the periodic table of elements. In some embodiments, the metal or metallic surface comprises one or more transition metals from groups 4 to 11 of the periodic table of elements. In some embodiments, a metal or metallic surface comprises aluminum (Al). In some embodiments, a metal or metallic surface comprises copper (Cu). In some embodiments, a metal or metallic surface comprises tungsten (W). In some embodiments, a metal or metallic surface comprises cobalt (Co). In some embodiments, a metal or metallic surface comprises nickel (Ni). In some embodiments, a metal or metallic surface comprises niobium (Nb). In some embodiments, the metal or metallic surface comprises iron (Fe). In some embodiments, the metal or metallic surface comprises molybdenum (Mo). In some embodiments, a metal or metallic surface comprises a metal selected from a group consisting of Al, Mn, Fe, Co, Ni, Cu, Zn, Nb, Mo, Ru and W. In some embodiments, the metal or metallic surface comprises a transition metal selected from a group consisting of Zn, Fe, Mn and Mo.

In some embodiments, a metallic surface comprises titanium nitride. In some embodiments, the metal or metallic surface comprises one or more noble metals, such as Ru. In some embodiments, the metal or metallic surface comprises a conductive metal oxide. In some embodiments, the metal or metallic surface comprises a conductive metal nitride. In some embodiments, the metal or metallic surface comprises a conductive metal carbide. In some embodiments, the metal or metallic surface comprises a conductive metal boride. In some embodiments, the metal or metallic surface comprises a combination conductive materials. For example, the metal or metallic surface may comprise one or more of ruthenium oxide (RuOx), niobium carbide (NbCx), niobium boride (NbBx), nickel oxide (NiOx), cobalt oxide (CoOx), niobium oxide (NbOx), tungsten carbonitride (WNCx), tantalum nitride (TaN), or titanium nitride (TiN).

In some embodiments, the second surface may comprise a passivated metal surface, for example a passivated Cu surface. That is, in some embodiments, the second surface may comprise a metal surface comprising a passivation agent, for example an organic passivation layer such as a polyimide passivation layer or a self-assembled monolayer. In some embodiments, the passivation layer remains on the second surface over at least two, such as at least about 10, about 20, about 50, about 100 or about 150 deposition cycles of the dielectric material. In other words, a passivation layer, such as polyimide-comprising layer, is used that is able to withstand the deposition conditions over an extended period of time.

In some embodiments, a dielectric material is selectively deposited on a first SiO₂ surface relative to a second dielectric surface. In some embodiments, a dielectric material is selectively deposited on a first Si or Ge surface relative to a second dielectric surface, for example an HF-dipped Si or HF-dipped Ge surface.

In some embodiments, a dielectric material is selectively deposited on a first dielectric surface of a substrate relative to a second metal or metallic surface of the substrate. In some embodiments, the second surface comprises a metal oxide, elemental metal, or metallic surface. In some embodiments, the second metal or metallic surface comprises a passivation layer comprising polyamic acid, polyimide, or other polymeric material.

In some embodiments, a substrate is provided comprising a first dielectric surface and a second metal or metallic surface. In some embodiments, a substrate is provided that comprises a first metal oxide surface. In some embodiments, the first surface may comprise —OH groups. In some embodiments, the first surface may be a SiO₂-based surface. In some embodiments, the first surface may comprise Si—O bonds. In some embodiments, the first surface may comprise a SiO₂-based low-k material. In some embodiments, the first surface may comprise more than about 30%, or more than about 50% of SiO₂. In certain embodiments, the first surface may comprise a silicon dioxide surface

In some embodiments, the first surface may comprise GeO₂. In some embodiments, the first surface may comprise Ge—O bonds. In some embodiments, a dielectric material is selectively deposited on a first Si or Ge surface, for example an HF-dipped Si or HF-dipped Ge surface, relative to a second metal or metallic surface. For example, in some embodiments, the first surface may comprise a naturally or chemically grown silicon dioxide surface. In some embodiments, the first surface may comprise a thermally grown silicon dioxide surface.

In certain embodiments the first surface may comprise a silicon oxide -based surface and the second dielectric surface may comprise a second, different silicon oxide -based surface. In other embodiments, the first or the second surface may be replaced with a deposited layer of dielectric material. Therefore, in some embodiments, dielectric material may be selectively deposited on a first silicon oxide-based surface of a substrate relative to a second silicon oxide -based surface that was formed by a different technique and therefore has different material properties, such as composition.

In some embodiments, the substrate may be pretreated or cleaned prior to or at the beginning of the selective deposition process. In some embodiments, the substrate may be subjected to a plasma cleaning process at prior to or at the beginning of the selective deposition process. In some embodiments, a plasma cleaning process may not include ion bombardment, or may include relatively small amounts of ion bombardment. For example, in some embodiments, the substrate surface may be exposed to plasma, radicals, excited species, and/or atomic species prior to or at the beginning of the selective deposition process. In some embodiments, the substrate surface may be exposed to hydrogen plasma, radicals, or atomic species prior to or at the beginning of the selective deposition process. In some embodiments, a pretreatment or cleaning process may be carried out in the same reaction chamber as a selective deposition process. However, in some embodiments, a pretreatment or cleaning process may be carried out in a separate reaction chamber.

### General Process

In the methods according to the current disclosure, a substrate is provided in a reaction chamber, a metal or metalloid catalyst is provided into the reaction chamber in a vapor phase, a thermal deposition subcycle is performed to selectively deposit a first material on the first surface and a plasma deposition subcycle is performed to selectively deposit a second material on the first surface. In the methods, at least one of the first material and the second material comprises silicon and oxygen. The term “catalyst” is used for metal or metalloid catalyst throughout the disclosure for simplicity.

The terms “precursor” and “reactant” can refer to molecules (compounds or molecules comprising a single element) that participate in a chemical reaction that produces another compound. A precursor typically contains portions that are at least partly incorporated into the compound or element resulting from the chemical reaction in question. Such a resulting compound or element may be deposited on a substrate. A reactant may be an element or a compound that is not incorporated into the resulting compound or element to a significant extent. However, a reactant may also contribute to the resulting compound or element in certain embodiments.

In some embodiments, a precursor is provided in a mixture of two or more compounds. In a mixture, the other compounds in addition to the precursor may be inert compounds or elements. In some embodiments, a precursor is substantially or completely formed of a single compound. In some embodiments, a precursor is provided in a composition. Composition may be a solution or a gas in standard conditions.

The current disclosure relates to a selective deposition process. Selectivity can be given as a percentage calculated by [(deposition on first surface)−(deposition on second surface)]/(deposition on the first surface). Deposition can be measured in any of a variety of ways. In some embodiments, deposition may be given as the measured thickness of the deposited material. In some embodiments, deposition may be given as the measured amount of material deposited.

In some embodiments, selectivity is greater than about 30%. In some embodiments, selectivity is greater than about 50%. In some embodiments, selectivity is greater than about 75% or greater than about 85%. In some embodiments, selectivity is greater than about 90% or greater than about 93%. In some embodiments, selectivity is greater than about 95% or greater than about 98%. In some embodiments, selectivity is greater than about 99% or even greater than about 99.5%. In embodiments, the selectivity can change over the duration or thickness of a deposition.

In some embodiments, deposition only occurs on the first surface and does not occur on the second surface. In some embodiments, deposition on the first surface of the substrate relative to the second surface of the substrate is at least about 80% selective, which may be selective enough for some particular applications. In some embodiments the deposition on the first surface of the substrate relative to the second surface of the substrate is at least about 50% selective, which may be selective enough for some particular applications. In some embodiments the deposition on the first surface of the substrate relative to the second surface of the substrate is at least about 10% selective, which may be selective enough for some particular applications.

In some embodiments the dielectric material that is selectively deposited on the first surface comprises a mixture of two or more oxides. In some embodiments, the oxide that is deposited comprises a mixture of silicon oxide and one or more metal oxides. In some embodiments an oxide is deposited that comprises metal and silicon, such as SiAlOx. In some embodiments a silicate is deposited.

In this disclosure, “gas” can include material that is a gas at normal temperature and pressure (NTP), a vaporized solid and/or a vaporized liquid, and can be constituted by a single gas or a mixture of gases, depending on the context. Precursors according to the current disclosure may be provided to the reaction chamber in gas phase. The term “inert gas” can refer to a gas that does not take part in a chemical reaction and/or does not become a part of a layer to an appreciable extent. Exemplary inert gases include He and Ar and any combination thereof. In some cases, molecular nitrogen and/or hydrogen can be an inert gas. A gas other than a process gas, i.e., a gas introduced without passing through a precursor injector system, other gas distribution device, or the like, can be used for, e.g., sealing the reaction space, and can include a seal gas.

### Cyclic Deposition Process

In embodiments of the current disclosure, cyclic vapor deposition methods are used to deposit dielectric material on the first surface. In some embodiments, cyclic CVD or atomic layer deposition (ALD) processes are used. After selective deposition of the dielectric material is completed, further processing can be carried out to form the desired structures.

In the current disclosure, the deposition process may comprise a cyclic deposition process, such as an atomic layer deposition (ALD) process or a cyclic chemical vapor deposition (VCD) process to deposit dielectric material. The term “cyclic deposition process” can refer to the sequential introduction of precursor(s) and/or reactant(s) into a reaction chamber to deposit material, such as a dielectric material, on a substrate. Cyclic deposition includes processing techniques such as atomic layer deposition (ALD), cyclic chemical vapor deposition (cyclic CVD), and hybrid cyclic deposition processes that include an ALD component and a cyclic CVD component. The process may comprise a purge step between providing precursors or between providing a precursor and a reactant in the reaction chamber.

The process may comprise one or more cyclic phases. For example, pulsing of silicon precursor and oxygen precursor may be repeated. In some embodiments, the process comprises or one or more acyclic phases. In some embodiments, the deposition process comprises the continuous flow of at least one precursor or plasma. In some embodiments, one or more of the precursors and/or reactants are provided in the reaction chamber continuously. In some embodiments, catalyst may be provided in the reaction chamber continuously.

The term “atomic layer deposition” (ALD) can refer to a vapor deposition process in which deposition cycles, such as a plurality of consecutive deposition cycles, are conducted in a reaction chamber. The term atomic layer deposition, as used herein, is also meant to include processes designated by related terms, such as chemical vapor atomic layer deposition, when performed with alternating pulses of precursor(s)/reactant(s), and optional purge gas(es). Generally, for ALD processes, during each cycle, a precursor is introduced to a reaction chamber and is chemisorbed to a deposition surface (e.g., a substrate surface that may include a previously deposited material from a previous ALD cycle or other material), forming about a monolayer or sub-monolayer of material that does not readily react with additional precursor (i.e., a self-limiting reaction). Thereafter, in some cases, another precursor or a reactant may subsequently be introduced into the process chamber for use in converting the chemisorbed precursor to the desired material on the deposition surface. The second precursor or a reactant can be capable of further reaction with the precursor. Purging steps may be utilized during one or more cycles, e.g., during each step of each cycle, to remove any excess precursor from the process chamber and/or remove any excess reactant and/or reaction byproducts from the reaction chamber. Thus, in some embodiments, the cyclic deposition process comprises purging the reaction chamber after providing a precursor into the reaction chamber. In some embodiments, the cyclic deposition process comprises purging the reaction chamber after providing a silicon precursor or a metal precursor into the reaction chamber. In some embodiments, the cyclic deposition process comprises purging the reaction chamber after providing an oxygen precursor or plasma into the reaction chamber. In some embodiments, the cyclic deposition process comprises purging the reaction chamber after providing a precursor into the reaction chamber, and after providing an oxygen precursor into the reaction chamber and providing a catalyst into the reaction chamber.

CVD type processes typically involve gas phase reactions between two or more precursors and/or reactants. The precursor(s) and reactant(s) can be provided simultaneously to the reaction space or substrate, or in partially or completely separated pulses. The substrate and/or reaction space can be heated to promote the reaction between the gaseous precursor and/or reactants. In some embodiments the precursor(s) and reactant(s) are provided until a layer having a desired thickness is deposited. In some embodiments, cyclic CVD processes can be used with multiple cycles to deposit a thin film having a desired thickness. In cyclic CVD processes, the precursors and/or reactants may be provided to the reaction chamber in pulses that do not overlap, or that partially or completely overlap.

The reaction chamber can form part of an atomic layer deposition (ALD) assembly. The reaction chamber can form part of a chemical vapor deposition (CVD) assembly. The assembly may be a single wafer reactor. Alternatively, the reactor may be a batch reactor. The assembly may comprise one or more multi-station deposition chambers. Various phases of method can be performed within a single reaction chamber or they can be performed in multiple reaction chambers, such as reaction chambers of a cluster tool. In some embodiments, the method is performed in a single reaction chamber of a cluster tool, but other, preceding or subsequent, manufacturing steps of the structure or device are performed in additional reaction chambers of the same cluster tool. Optionally, an assembly including the reaction chamber can be provided with a heater to activate the reactions by elevating the temperature of one or more of the substrate and/or the reactants and/or precursors. The dielectric material according to the current disclosure may be deposited in a cross-flow reaction chamber. The dielectric material according to the current disclosure may be deposited in a showerhead-type reaction chamber.

The methods according to the current disclosure comprise a thermal deposition subcycle and a plasma deposition subcycle. Such an approach may allow for combining benefits from both methodologies. In particular, it may improve the selectivity of deposition relative to pure plasma processes, while producing better-quality material than thermal processes. Same silicon precursor, metal precursor or a semimetal precursor may be utilized in both thermal and plasma deposition subcycles. Due to the difference in the deposition process, the thermal and plasma subcycles may produce material having different characteristics. Depending on the deposited dielectric materials and process specifics, such as the number of subcycles used for each of the thermal and plasma subcycles, the two materials may intermix or remain partially or fully separate. If the deposited materials remain at least partially separate, a nanolaminate structure may be formed.

In the embodiments of the current disclosure, in at least one of the thermal deposition subcycle and the plasma deposition subcycle material comprising silicon and oxygen is deposited. In some embodiments, material comprising silicon and oxygen is deposited in both subcycles. In some embodiments, in one of the thermal deposition subcycle and plasma deposition subcycle, a metal or metalloid oxide is deposited.

In some embodiments, the plasma deposition subcycle is performed last. The plasma deposition subcycle may be used, for example, to deposit a capping layer, a sealing layer or an etch-stop layer. This may be due to the lower wet etch rate of materials deposited by a plasma process. Additionally, k value of the deposited dielectric material may be adjusted by selecting a suitable plasma deposition process. In some embodiments, material comprising silicon and oxygen deposited by a thermal process may be more porous than material deposited by a plasma-enhanced process. A topmost layer of material deposited by a plasma-enhanced process may, in addition to protecting the underlying material, cure the underlying material and thus improve its properties. For the deposition of a resistant top layer, using a deposition process comprising the use of an oxygen-containing silicon precursor and hydrogen plasma, leading to carbide-containing material comprising silicon and oxygen, may be beneficial.

In some embodiments, two different plasma deposition subcycles may be performed in a deposition process. In some embodiments, such different plasma deposition subcycles are performed without a thermal deposition subcycle in between. Thus, a layer comprising, for example, silicon, oxygen and a metal, such as aluminum, may be deposited. Similarly, performing two different thermal deposition processes may be useful in some applications.

In some embodiments, the first material is aluminum oxide (Al₂O₃). In some embodiments, the first material is silicon oxide (SiO₂) or a material comprising substantially only of silicon oxide. In some embodiments, the second material is aluminum oxide (Al₂O₃). In some embodiments, the second material is silicon oxide (SiO₂) or a material comprising substantially only of silicon oxide. In some embodiments, the first material is aluminum oxide (Al₂O₃) and the second material is silicon oxide (SiO₂) or a material comprising substantially only of silicon oxide. In some embodiments, the first material is silicon oxide (SiO₂) or a material comprising substantially only of silicon oxide and the second material is aluminum oxide (Al₂O₃). In some embodiments, the first material is silicon oxide (SiO₂) or a material comprising substantially only of silicon oxide and the second material is silicon oxide (SiO₂) or a material comprising substantially only of silicon oxide. In some embodiments, the above silicon oxide-based material comprises silicon oxycarbide.

### Purging

As used herein, the term “purge” may refer to a procedure in which vapor phase precursors and/or vapor phase byproducts are removed from the substrate surface for example by evacuating the reaction chamber with a vacuum pump and/or by replacing the gas inside a reaction chamber with an inert or substantially inert gas such as argon or nitrogen. Purging may be effected between two pulses of gases which react with each other. However, purging may be effected between two pulses of gases that do not react with each other. For example, a purge, or purging may be provided between pulses of two precursors or between a catalyst and a precursor. Purging may avoid, or at least reduce, gas-phase interactions between the two gases reacting with each other.

It shall be understood that a purge can be effected either in time or in space, or both. For example in the case of temporal purges, a purge step can be used e.g. in the temporal sequence of providing a first precursor to a reactor chamber, providing a purge gas to the reactor chamber, and providing a second precursor to the reactor chamber, wherein the substrate on which a material is deposited does not move. For example in the case of spatial purges, a purge step can take the following form: moving a substrate from a first location to which a first precursor is continually supplied, through a purge gas curtain, to a second location to which a second precursor is continually supplied. Purging times may be, for example, from about 0.01 seconds to about 20 seconds, from about 0.05 s to about 20 s, or from about 1 s to about 20 s, or from about 0.5 s to about 10 s, or between about 1 s and about 7 seconds, such as 5 s, 6 s or 8 s. However, other purge times can be utilized if necessary, such as where highly conformal step coverage over extremely high aspect ratio structures or other structures with complex surface morphology is needed, or in specific reactor types, such as a batch reactor, may be used.

### Catalyst

A metal or metalloid catalyst (“catalyst”) is used to enhance or to enable deposition of dielectric material on the first surface. Especially, to obtain advantages according to the current disclosure, a silicon precursor as described above may be combined with a catalyst. This may allow the deposition using an alkoxy silane according to the current disclosure while retaining selectivity of deposition.

In the embodiments of the current disclosure, a metal or metalloid catalyst (“catalyst”) is provided into the reaction chamber in a vapor phase. In some embodiments, the catalyst is provided before a thermal deposition subcycle. In some embodiments, the catalyst is provided before a plasma deposition subcycle. In some embodiments, the catalyst is provided before a thermal deposition subcycle and before a plasma deposition subcycle. Especially in embodiments, in which metal or metalloid oxide is deposited, the catalyst and the deposited oxide may comprise the same metal or metalloid element. In such embodiments, providing a catalyst into the reaction chamber may be merged with a deposition subcycle in which a metal or metalloid oxide is deposited.

The catalyst may be provided to the reaction chamber holding the substrate in a single pulse or in a sequence of multiple pulses. In some embodiments, the catalyst is provided in a single long pulse. In some embodiments, the catalyst is provided in multiple shorter pulses, such as from 2 to about 30 pulses. The pulses may be provided sequentially. There may be a purge between two consecutive catalyst pulses.

A catalyst is selectively provided on the first surface relative to the second surface, such as by providing a catalyst into the reaction chamber. Therein, the catalyst contacts the substrate. The first surface may be a dielectric surface, and the second surface may be a metal surface. In some embodiments, the substrate is contacted with a catalyst as described below.

A catalyst according to the current disclosure is a metal or metalloid catalyst. In some embodiments, the catalyst is a metal or metalloid compound comprising B, Zn, Mg, Mn, La, Hf, Al, Zr, Ti, Sn, or Ga. In some embodiments, the catalyst is an alkylaluminium, alkylboron or alkylzinc compound that is able to react with the first surface. For example, the catalyst may comprise trimethyl aluminum (TMA), triethylboron (TEB), or diethyl zinc. In some embodiments, the catalyst is a metal catalyst. In some embodiments, the catalyst is a metal halide, organometallic or metalorganic compound. In some embodiments, the catalyst is a metal oxide.

In some embodiments, the catalyst comprises a compound having the formula MRₓA₃₋ₓ, wherein x is from 1 to 3, R is a C1-C5 alkyl ligand, M is B, Zn, Mg, Mn, La, Hf, Al, Zr, Ti, Sn, or Ga and A is a halide, alkylamine, amino, silyl or derivative thereof. In some embodiments, R is a C1-C3 alkyl ligand. In some embodiment R is a methyl or ethyl group. In some embodiments, the M is boron. In some embodiments, the catalyst is ZnRₓA₂₋ₓ, wherein x is from 1 to 2, R is a C1-C5 alkyl ligand, and A is a halide, alkylamine, amino, silyl or derivative thereof. In some such embodiments R is a C1-C3 alkyl ligand. In some embodiment R is a methyl or ethyl group.

In some embodiments, the catalyst is an aluminum catalyst. In some embodiments, the catalyst is an aluminum catalyst comprising trimethyl aluminum (TMA), dimethylaluminumchloride, aluminum trichloride (AlCl₃), dimethylaluminum isopropoxide (DMAI), tris(tertbutyl)aluminum (TTBA), tris(isopropoxide)aluminum (TIPA), tris(dimethylamino) aluminum (TDMAA) or triethyl aluminum (TEA). In some embodiments, the aluminum catalyst is a heteroleptic aluminum compound. In some embodiments, the heteroleptic aluminum compound comprises an alkyl group and another ligand, such as a halide, for example Cl. In some embodiments, the aluminum catalyst comprises dimethylaluminumchloride. In some embodiments, the aluminum catalyst comprises an alkyl precursor comprising two different alkyl groups as ligands. In some embodiments, the aluminum compound is an aluminum isopropoxide. In some embodiments, the aluminum catalyst comprises a metalorganic compound. In some embodiments, the aluminum catalyst comprises an organometallic compound. In some embodiments, the aluminum catalyst is an aluminum compound such as trimethyl aluminum (TMA), dimethylaluminumchloride, aluminum trichloride (AlCl3), dimethylaluminum isopropoxide (DMAI), tris(tertbutyl)aluminum (TTBA), tris(isopropoxide)aluminum (TIPA), tris(dimethylamino) aluminum (TDMAA) or triethyl aluminum (TEA).

In some embodiments, the catalyst is a zirconium compound, such as bis(methylcyclopentadienyl)methoxymethyl zirconium (ZrD-04). In some embodiments, the catalyst is tetrakis(ethylmethylamino)zirconium (TEMAZ). In some embodiments, the catalyst is ZrCl₄.

In some embodiments, the catalyst is a lanthanum compound, such as tris(isopropyl-cyclopentadienyl)lanthanum (La(iPrCp)₃). In some embodiments, the catalyst is a titanium compound, such as titanium isopropoxide (TTIP) or TiCl₄. In some embodiments, the catalyst is a gallium compound, such as trimethylgallium (TMG). In some embodiments, the catalyst is a hafnium compound, such as HfD-04, HfCl₄ or Hf(NO₃)₄.

In some embodiments, the metal or metalloid catalyst is a metalloid catalyst. In some embodiments, the catalyst comprises an alkylborane. In some embodiments, the catalyst comprises a trialkylborane. In some embodiments, the catalyst comprises a trimethylborane or a triethylborane.

In some embodiments, the catalyst may preferentially chemisorb on a dielectric surface, for example on a dielectric surface, optionally comprising a blocking agent, relative to a passivated metal surface. In some embodiments, the catalyst preferentially deposits on the dielectric surface relative to the passivated metal surface. In some embodiments, the passivating agent on the metal surface inhibits or prevents deposition of catalyst on the metal surface. In some embodiments, a single exposure to the passivating agent may prevent deposition of catalyst on the metal surface for 1, 2, 5, 10, 20, 30, 40 or 50 or more cycles in which the substrate is contacted with the catalyst. In some embodiments, the second surface is not passivated and the catalyst selectively chemisorbs on the dielectric surface in the absence of a passivating agent on the metal surface. For example, the catalyst may selectively deposit on a first dielectric surface relative to a second surface. In some embodiments, the first dielectric surface comprises a blocking agent. In some embodiments, a catalyst is not utilized.

After contacting the catalyst with the dielectric surface, dielectric material is selectively deposited on the dielectric surface relative to the passivated second surface. For example, the substrate may be exposed to a silicon precursor, such as an alkoxy silane. In some embodiments, the substrate is exposed to the silicon precursor alone, while in some embodiments, the substrate is exposed to the silicon precursor and an oxygen precursor, such as H₂O. In thermal deposition subcycle, the substrate may be exposed to plasma, such as argon or plasma, after exposing the substrate to a silicon precursor. The silicon precursor and the oxygen precursor or plasma may react with the surface comprising the catalyst to form dielectric material. For example, the substrate may be contacted with a silicon precursor comprising an alkoxy silane such that the alkoxy silane decomposes at the catalyst atoms on the dielectric surface, resulting in the selective growth of material comprising silicon and oxygen on the dielectric surface relative to the second surface. In some embodiments, the substrate may be exposed to a metal precursor, such as an aluminum precursor, and exposed to an oxygen precursors, plasma or both. Although the term “catalyst” is used in describing the processes on the substrate surface, it is appreciated that in reality, the surface-bound, catalytically active substance may be chemically different from the substance provided into the reaction chamber in vapor phase.

The catalyst may be provided to the reaction chamber holding the substrate in a single pulse or in a sequence of multiple pulses. In some embodiments, the catalyst is provided in a single long pulse. In some embodiments, the catalyst is provided in multiple shorter pulses. The pulses may be provided sequentially. In some embodiments, the catalyst is provided in 1 to 25 pulses of from about 0.1 to about 60 seconds. In some embodiments, the catalyst is provided in a single pulse of about 0.1 to about 60 seconds, about 1 to 30 seconds or about 25 seconds. In some embodiments, the catalyst is provided into the reaction chamber in every deposition cycle. In some embodiments, the catalyst is provided into the reaction chamber in every deposition cycle in a single pulse. The pulse length in each deposition cycle may be from about 0.1 seconds to about 10 seconds, such as from about 1 second to about 5 seconds. In between catalyst pulses, excess catalyst may be removed from the reaction space. For example, the reaction chamber may be evacuated and/or purged with an inert gas. The purge may be, for example for about 1 to 30 seconds or more. Purging means that vapor phase catalyst and/or vapor phase byproducts, if any, are removed from the reaction chamber such as by evacuating the chamber with a vacuum pump and/or by replacing the gas inside the reaction chamber with an inert gas. In some embodiments, vapor phase catalyst is removed from the substrate surface by moving the substrate from the reaction space comprising the vapor phase catalyst.

### Silicon Precursor

As used herein, “silicon precursor” includes a gas or a material that can become gaseous and that can be represented by a chemical formula that includes silicon. A silicon precursor according to the current disclosure comprises an alkoxy silane. In some embodiments, a silicon precursor is an alkoxy silane. In some embodiments, a silicon precursor does not contain hydroxyl groups. In some embodiments, an alkoxy silane according to the current disclosure comprises four identical alkoxy groups. In some embodiments, an alkoxy silane according to the current disclosure comprises a carboxylate group. In some embodiments, an alkoxy silane according to the current disclosure comprises a silyl ester. In some embodiments, the alkoxy silane is selected from a group consisting of tetraacetoxysilane (tetraacetyl ortosilicate), tetramethoxysilane, tetraethoxysilane (tetraethyl ortosilicate), trimethoxysilane, triethoxysilane and trimethoxy(3-methoxypropyl)silane. In some embodiments, a trialkoxy silane according to the current disclosure comprises a compound of formula RSi(OR′)₃, wherein R is selected from H, 3-aminopropyl, CHCH₃, 3-methoxypropyl, and R′ is selected from CH₃ and CH₂CH₃. In some embodiments, a triethoxy silane according to the current disclosure comprises a compound of formula HSi(OCH₂CH₃)₃. In some embodiments, a triethoxy silane according to the current disclosure comprises triethoxy-3-aminopropyl silane (Si(OCH₂CH₃)₃CH₂CH₂CH₂NH₂). In some embodiments, a triethoxy silane according to the current disclosure comprises triethoxy(ethyl)silane (Si(OCH₂CH₃)₃CHCH₃).

Alkoxy silanes, for example tetraethoxysilane, may have advantages over other silicon precursors in selective deposition applications, as their reactivity is lower. In some embodiments, the silicon precursor does not contain hydroxyl groups. This may apply for OH groups available on the surface of dielectric materials and for metal and metallic surfaces. Alkoxy silanes may also have lower reactivity towards organic passivation agents. In some embodiments, the reduced reactivity towards passivation agents is more pronounced than towards dielectric surfaces. In some embodiments, it is possible to select the process conditions in a way, that growth of material comprising silicon and oxygen on organic passivation is substantially completely prevented. The reduced reactivity of alkoxy silanes towards organic passivation agents, such as polyimide and/or polyamic acid, may also be more robust than for other silicon precursors, and may be able to tolerate some plasma-induced damage on an organic passivation agent. Taken together, alkoxy silanes in general, and tetraethoxysilane in particular, may have a wider selectivity window compared to methods known in the art.

In some embodiments, the silicon precursor is provided two or more times in at least one material comprising silicon and oxygen deposition subcycle. In some embodiments, the silicon precursor is provided in two or more consecutive pulses during a deposition cycle. In some embodiments, the silicon precursor comprises tetraethoxysilane. In some embodiments, the silicon precursor consists essentially of tetraethoxysilane. In some embodiments, the silicon precursor comprises trimethoxy(3-methoxypropyl)silane. In some embodiments, the silicon precursor consists essentially of trimethoxy(3-methoxypropyl)silane.

### Metal Precursor

Dielectric material according to the current disclosure may comprise a metal or a semimetal and oxygen. For simplicity the term “metal precursor” is used throughout the disclosure, to refer also to precursors for metalloid elements.

In some embodiments, the deposited dielectric material comprises a metal oxide. In some embodiments, the metal oxide comprises zirconium oxide, hafnium oxide, aluminum oxide, titanium oxide, tantalum oxide, yttrium oxide, lanthanide oxide, such as lanthanum oxide, or other transition metal oxide or mixtures thereof. In some embodiments, the metal oxide comprises a dielectric transition metal oxide. In some embodiments, the metal oxide comprises aluminum oxide. In some embodiments, the aluminum oxide is deposited using an aluminum precursor comprising trimethyl aluminum (TMA), dimethylaluminumchloride, aluminum trichloride (AlCl₃), dimethylaluminum isopropoxide (DMAI) or triethyl aluminum (TEA). In some embodiments, the aluminum oxide is deposited using an aluminum precursor comprising a heteroleptic aluminum compound comprising an alkyl group and another ligand, such as a halide, for example Cl. In some embodiments, the aluminum oxide is deposited using an aluminum precursor comprising an aluminum alkyl compound comprising two different alkyl groups as ligands. In some embodiments, the aluminum compound is deposited using an aluminum precursor comprising a metalorganic aluminum compound or an organometallic aluminum compound.

A dielectric material deposited according to the current disclosure may include a metal element. Examples of the layer of interest include dielectrics, such as zirconium oxide (e.g., ZrO₂), hafnium oxide (e.g., HfO₂), aluminum oxide (e.g. Al₂O₃), and titanium oxide (e.g., TiO₂).

In some embodiments, aluminum oxide is deposited in a thermal deposition subcycle by providing a metal precursor comprising aluminum and an oxygen precursor into a reaction chamber. In some embodiments, aluminum oxide is deposited in a plasma deposition subcycle by providing a metal precursor comprising aluminum and plasma into a reaction chamber. The metal precursor comprising aluminum may comprise consist essentially of, or consist of, trimethyl aluminum (TMA), aluminum trichloride (AlCl₃), dimethylaluminum isopropoxide (DMAI) and triethyl aluminum (TEA). In some embodiments, the aluminum precursor is a heteroleptic aluminum compound. In some embodiments the heteroleptic aluminum compound comprises an alkyl group and another ligand, such as a halide, for example Cl. In some embodiments the aluminum compound is dimethylaluminumchloride. In some embodiments, the aluminum precursor is an alkyl precursor comprising two different alkyl groups as ligands. In some embodiments, the aluminum precursor is a metalorganic compound. In some embodiments, the aluminum precursor is an organometallic compound. In some embodiments, aluminum oxide is deposited by a thermal ALD-type process in which the substrate is alternately and sequential contacted with DMAI and water or H₂O. In some embodiments, aluminum oxide is deposited by a plasma-enhanced ALD-type process in which the substrate is alternately and sequential contacted with DMAI and plasma. In some embodiments, the plasma is generated from a noble gas, such as argon. In some embodiments, the temperature in the reaction chamber during aluminum oxide deposition is from about 150° C. to about 400° C. The pulse time for the reactants may be from about 0.1 to about 10 seconds, and the purge time between reactant pulses may also be from about 0.1 to about 10 seconds. The reaction chamber pressure may be, for example, from about 10-5 to about 760 Torr, or in some embodiments from about 1 to 10 Torr.

### Oxygen Precursor

A thermal deposition subcycle according to the current disclosure comprises providing an oxygen precursor into the reaction chamber. In embodiments, in which material comprising silicon and oxygen is deposited in the thermal deposition subcycle, the oxygen precursor is provided into the reaction chamber to react it with a silicon precursor to form material comprising silicon and oxygen on the first surface of the substrate. In embodiments, in which material comprising a metal and oxygen is deposited in the thermal deposition subcycle, the oxygen precursor is provided into the reaction chamber to react it with a metal precursor to form material comprising metal and oxygen on the first surface of the substrate. In embodiments, in which material comprising a metalloid and oxygen is deposited in the thermal deposition subcycle, the oxygen precursor is provided into the reaction chamber to react it with a metalloid precursor to form material comprising metalloid and oxygen on the first surface of the substrate.

An oxygen precursor according to the current disclosure comprises hydrogen and oxygen. In some embodiments, the oxygen precursor does not contain carbon, i.e. it is carbon-free. In some embodiments, the oxygen precursor does not contain silicon, i.e. it is silicon-free. In some embodiments, the oxygen precursor comprises water. In some embodiments, the oxygen precursor is water. In some embodiments, the oxygen precursor comprises hydrogen peroxide. In some embodiments, the oxygen precursor is hydrogen peroxide. Depending on the selected oxygen precursor, it may be liquid or gaseous in the precursor vessel upon vaporization. Also solid precursors may be used.

In some embodiments, the oxygen precursor comprises a carboxyl group. In some embodiments, the oxygen precursor comprises a carboxylic acid. A carboxyl group-comprising oxygen precursor may be a C1 to C7 carboxylic acid, or a C1 to C3 carboxylic acid. Exemplary carboxylic acids according to the current disclosure are formic acid, acetic acid, propionic acid, butyric acid, pentanoic acid, hexanoic acid, heptanoic acid, isobutyric acid, 2-methylbutanoic acid, 3-methylbutanoic acid, pivalic acid, 2,2-dimethylbutanoic acid, 2-methylpentanoic acid, 3-methylpentanoic acid, 2-ethylbutanoic acid, 2-ethylpentanoic acid and 2,3-dimethylbutanoic acid.

In some embodiments, the method comprises using two oxygen precursors. For example, a carboxylic acid, such as formic acid, and water may be used as oxygen precursors. In some embodiments, a thermal deposition subcycle comprises providing oxygen precursors three times into the reaction chamber, for example by alternating two oxygen precursors. In some embodiments, the silicon precursor may be provided in multiple pulses in a thermal deposition subcycle, separated by an optional purge in between. The various reactants may be provided into the reaction chamber in different order within a thermal deposition subcycle. As described above, a catalyst may be provided into the reaction chamber during a thermal deposition subcycle.

### Plasma

In a plasma deposition subcycle, plasma is provided into the reaction chamber for depositing material comprising silicon and oxygen on the substrate. Plasma is generated from a gas, which is herein termed a plasma precursor for simplicity. It is understood that the gas may be provided from a vessel, in which the gas can be present in a gas phase or in a liquid phase, depending on the element and design choices of the deposition assembly used for the deposition process. To deposit an oxide material through a plasma-enhanced process, in which the plasma does not comprise oxygen, the silicon precursor or the metal precursor comprises oxygen, and the deposition of oxide material is attributable to the reactions of the precursor enabled by the plasma treatment.

In the current disclosure, the use of a plasma deposition subcycle may have at least twofold benefits. First, using plasma may lead to material improvement—especially in embodiments in which both thermal and plasma deposition subcycles are used to deposits material comprising silicon and oxygen. A plasma treatment may lead to the densification of underlying thermally deposited material in addition to the deposition of material during the plasma deposition subcycle. Electrical performance of the deposited material may thus be improved. The use of a plasma deposition subcycle may allow tuning of material etch properties. The plasma deposition subcycle may be used to deposit a material of different composition on the underlying thermally deposited material, such as material comprising silicon and oxygen. The material deposited by a plasma deposition subcycle may be an etch stop layer. In such embodiments, there may be only one thermal deposition subcycle repeated until a layer of desired thickness is achieved, after which a plasma deposition subcycle is performed to deposit an etch-stop layer. For example a silicon precursor, for example trimethoxy(3-methoxypropyl)silane, may be used together with plasma generated from gas comprising hydrogen may be used to deposit silicon oxycarbide -containing material. Alternatively, aluminum oxide may be deposited by using an aluminum -containing metal precursor and plasma.

In some embodiments, plasma is generated from a gas containing substantially only a noble gas. In some embodiments, the plasma is generated from a noble gas. In such embodiments, the plasma precursor is thus a noble gas. In some embodiments, the noble gas is selected from a group consisting of helium, neon and argon. In some embodiments, the plasma is generated from a gas comprising only, or substantially only, one or more noble gases. In some embodiments, the plasma is generated from a gas comprising only, or substantially only, one noble gas. In some embodiments, the plasma is generated from a gas comprising only, or substantially only, argon. In such embodiments, the plasma precursor is thus argon. In some embodiments, the plasma is generated from a gas comprising only, or substantially only, helium. In some embodiments, the plasma is generated from a gas comprising only, or substantially only, neon. In some embodiments, the plasma is generated from a gas comprising only, or substantially only, neon. In some embodiments, the plasma is generated from a noble gas and an additional element. In some embodiments, the additional element is selected from hydrogen and nitrogen. In some embodiments, plasma is generated from a gas containing substantially only a noble gas and hydrogen. In some embodiments, the plasma is generated from gas comprising substantially only argon and hydrogen. In some embodiments, the additional element is nitrogen. In some embodiments, plasma is generated from a gas containing substantially only argon and nitrogen. In some embodiments, the additional element is nitrogen, and the material comprising silicon and oxygen further comprises nitrogen. However, in some embodiments, plasma may be generated from a gas containing three elements or compounds. In some embodiments, plasma may be generated from a gas containing four elements or compounds.

The plasma ion energy may be kept low in the embodiments of the current disclosure. Plasma ion energy may affect the likelihood of both damaging surfaces, such as passivation layers, on the substrate and rate of process. Too high plasma energy may damage possible passivation layer, and adversely affect the selectivity of the deposition. In some embodiments, the plasma is RF plasma, and the plasma power does not exceed 100 W. In some embodiments, plasma ion energy does not exceed 160 eV. In some embodiments, the maximum ion energy of the plasma is from about 25 eV to about 160 eV, such as from about 30 eV to about 150 eV or from about 30 eV to about 120 eV, or from about 30 eV to about 70 eV. In some embodiments, the maximum ion energy of the plasma is about 40 eV about 50 eV, about 60 eV, about 80 eV or 100 eV. Using mild plasma treatment to deposit material comprising silicon and oxygen according to the current disclosure may avoid the use of oxidizers, such as water, if so desired. The growth rate of the material comprising silicon and oxygen may still remain relatively fast in the absence of oxidizers, possibly providing advantages in high-volume manufacturing.

In some embodiments, plasma is generated from a gas comprising substantial amounts of hydrogen. In some embodiments, the plasma is generated from a gas comprising substantially only hydrogen, i.e. the plasma is hydrogen plasma. In some embodiments, a metal precursor comprising oxygen and hydrogen plasma are provided into the reaction chamber. In some embodiments, the gas from which plasma is generated does not comprise oxygen. The hydrogen plasma may be generated in a gas comprising, consisting substantially of or consisting of H₂. In some embodiments, plasma is generated from a gas comprising hydrogen and nitrogen. The reactive species of the plasma react with the metal or silicon precursor adsorbed on the first surface of the substrate to selectively form an oxide on the first surface relative to the second surface. In some embodiments in which hydrogen plasma is used, the deposited dielectric material comprises carbon. In some embodiments, the deposited dielectric material comprises silicon oxycarbide.

Without limiting the current disclosure to any specific theory, the silicon precursor may chemisorb onto the substrate surface through -OH groups available on the substrate surface. An oxygen atom of an alkoxy group in the silicon precursor may react with the substrate surface, leading to bonding between surface-bound oxygen and the silicon atom of the alkoxy silane.

### Material Comprising Silicon and Oxygen

Material comprising silicon and oxygen according to the current disclosure may comprise, consist essentially of, or consist of silicon oxide, such as silicon dioxide. However, in some embodiments, the material comprising silicon and oxygen comprises additional elements, such as aluminum (Al). In some embodiments, the material comprising silicon and oxygen comprises, consists substantially of, or consists of metal silicate, such as aluminum silicate. The methods according to the current disclosure allow for the deposition of materials comprising silicon, oxygen and a metal, such that the amount of the metal is adjustable. Alternating thermal and plasma deposition processes through the respective subcycles, nanolaminate structure of alternating composition may be deposited. In some embodiments, the thermal and plasma subcycles may be alternated frequently enough for the materials produced by the two types of processes are mixed. The materials may comprise silicon and oxygen and/or metal and oxygen.

In some embodiments, a layer of material comprising silicon and oxygen is deposited. As used herein, the term “layer” and/or “film” can refer to any continuous or non-continuous structure and material, such as material deposited by the methods disclosed herein. For example, layer and/or film can include two-dimensional materials, three-dimensional materials, nanoparticles or even partial or full molecular layers or partial or full atomic layers or clusters of atoms and/or molecules. A film or layer may comprise material or a layer with pinholes, which may be at least partially continuous. A seed layer may be a non-continuous layer serving to increase the rate of nucleation of another material. However, the seed layer may also be substantially or completely continuous.

A layer of material comprising silicon and oxygen of desired thickness may be deposited by a cyclic deposition process according to the current disclosure. In some embodiments, the layer comprising silicon and oxygen is substantially continuous. In some embodiments, the layer comprising silicon and oxygen is continuous. In some embodiments, the layer comprising silicon and oxygen has an approximate thickness of at least about 0.5 nm. In some embodiments, the layer comprising silicon and oxygen has an approximate thickness of at least about 1 nm. In some embodiments, the layer comprising silicon and oxygen has an approximate thickness of at least about 5 nm. In some embodiments, the layer comprising silicon and oxygen has an approximate thickness of at least about 10 nm. In some embodiments, the layer comprising silicon and oxygen has an approximate thickness of about 1 nm to about 50 nm. In some embodiments, a substantially or completely continuous layer comprising silicon and oxygen having a thickness of less than 10 nm, such as from about 4 nm to about 8 nm, for example about 5 nm or about 6 nm may be selectively deposited on the first surface of the substrate.

In some embodiments, the silicon to metal ratio of material comprising silicon and oxygen is equal to or larger than about 3. In some embodiments, the silicon to metal ratio of material comprising silicon and oxygen is equal to or larger than about 4. In some embodiments, the silicon to metal ratio of material comprising silicon and oxygen is equal to or larger than about 5, such as about 6. In some embodiments, the silicon-to-metal ratio of material comprising silicon and oxygen is from about 2.5 to about 6, such as from about 3 to about 5.

In some embodiments, the k value of material comprising silicon and oxygen deposited according to the current disclosure is below about 5, or below about 4.

In some embodiments, the wet etch resistance of material comprising silicon and oxygen according to the current disclosure is from about 0.1 to about 1 nm/s, as measured by exposure to 0.5% HF, and depending on the composition of the material comprising silicon and oxygen. In some embodiments, the wet etch resistance rate is about 0.2 nm/s as measured by exposure to 0.5%.

### Material Comprising a Metal Oxide or a Metalloid Oxide

In some embodiments, a metal oxide or a metalloid oxide is deposited in one of the thermal deposition subcycle and the plasma deposition subcycle. By a metalloid in the current disclosure is meant an element of group 13 from the periodic table of elements, such as boron. In some embodiments, the metal oxide comprises zirconium oxide, hafnium oxide, aluminum oxide, titanium oxide, tantalum oxide, yttrium oxide, lanthanide oxide, such as lanthanum oxide, or other transition metal oxide or mixtures thereof. In some embodiments, the metal oxide comprises a dielectric transition metal oxide. A metal oxide may be deposited as a separate layer, or it may be mixed with material comprising silicon and oxygen. In some embodiments, the deposited dielectric material comprises a metal silicate, such as aluminum silicate.

### Thermal Deposition Subcycle

In embodiments according to the current disclosure, the cyclic deposition process comprises a thermal deposition process. In thermal deposition, the chemical reactions are promoted by increased temperature relevant to ambient temperature. Generally, temperature increase provides the energy needed for the formation of dielectric material in the absence of other external energy sources, such as plasma, radicals, or other forms of radiation. In some embodiments, the vapor deposition process according to the current disclosure is a thermal ALD process. A thermal deposition subcycle according to the current disclosure may allow to preserve an inhibition layer during performing the deposition process, which may improve the selectivity of the deposition process. However, plasma is utilized in the plasma deposition subcycle and may be utilized in other process phases, such as etching away unwanted materials.

In some embodiments, first material deposited by the thermal deposition subcycle is a material comprising silicon and oxygen. A thermal deposition subcycle for depositing a material comprising silicon and oxygen comprises providing a silicon precursor comprising an alkoxy silane compound into the reaction chamber in a vapor phase and providing an oxygen precursor comprising oxygen and hydrogen into the reaction chamber in vapor phase to form first material comprising silicon and oxygen on the first surface.

In some embodiments, a catalyst, a silicon precursor and an oxygen precursor are all provided into the reaction chamber during one thermal deposition subcycle. Thus, a deposition process comprises at least one thermal subcycle in which the catalyst, the silicon precursor and the oxygen precursor are provided into the reaction chamber. In some embodiments, substantially all the thermal subcycles of a deposition process comprise providing the catalyst, the silicon precursor and the oxygen precursor into the reaction chamber.

A silicon precursor an oxygen precursor, as well as an optional catalyst may be provided into the reaction chamber in various schemes. For example, all of them may be provided as single consecutive and separated pulses. Alternatively, two—or three if a catalyst is provided—of the reactants may be provided at least partially simultaneously into the reaction chamber. In some embodiments, two or more of the reactants are provided in a fully overlapping manner. In some embodiments, two of the reactants may be co-pulsed, i.e. the two reactants are provided at least partially simultaneously into the reaction chamber. For example, in some embodiments, it may be advantageous to provide a catalyst and a silicon precursor simultaneously into the reaction chamber. In some embodiments, the pulses of catalyst and the silicon precursor overlap partially. In some embodiments, the pulses of catalyst and the silicon precursor overlap at least partially. In some embodiments, the pulses of catalyst and the silicon precursor overlap completely. Further, in some embodiments, a deposition subcycle may comprise co-pulsing a silicon precursor and an oxygen precursor. For example, tetraethoxysilane and water, or tetraethoxysilane and formic acid may be provided into the reaction chamber at least partially simultaneously. It may also be advantageous to co-pulse two different oxygen precursors, for example water and a carboxylic acid.

The silicon precursor may be provided to the reaction chamber holding the substrate in a single pulse or in a sequence of multiple pulses. In some embodiments, the silicon precursor is provided in a single long pulse. In some embodiments, the silicon precursor is provided in multiple shorter pulses, such as from 2 to about 30 pulses. For example, a subcycle may comprise providing the silicon precursor into the reaction chamber in multiple pulses, for example, in about 15 to about 25 pulses, and then providing an oxygen precursor into the reaction chamber in a single pulse. The pulses may be provided sequentially. There may be a purge between two consecutive silicon precursor pulses.

### Plasma Deposition Subcycle

In a plasma deposition subcycle, plasma is provided into the reaction chamber to form a reactive species for forming a dielectric material on the first surface. Thus, the cyclic deposition methods according to the current disclosure have a plasma-enhanced deposition component. Plasma-enhanced cyclic deposition may be performed as, for example, plasma-enhanced atomic layer deposition (PEALD) or plasma-enhanced cyclic chemical vapor deposition (cyclic PECVD).

In some embodiments, plasma may be formed remotely via plasma discharge (“remote plasma”) away from the substrate or reaction space. In some embodiments, plasma may be formed in the vicinity of the substrate or directly above substrate (“direct plasma”). In some embodiments, the plasma is produced by gas-phase ionization of a gas with a radio frequency (RF) power. The power for generating RF-generated plasma can be varied in different embodiments of the current disclosure. In some embodiments, the RF power is between 30 W and 100 W. In some embodiments, the RF power may be from 30 W to 80 W, such as, 40 W, 50 W or 60 W. In some embodiments, the RF power may be from 30 W to 70 W. Adjusting the power of the RF plasma generator during the deposition of the dielectric material may affect the amount/density and energy of reactive species generated by plasma. Without limiting the current invention to any specific theory, higher RF power may lead to generation of higher energy ions and radicals. This may affect the damage the reactive species cause on the surfaces of the substrate. For example, in embodiments in which the second surface comprises a passivation layer, too high plasma power should be avoided. The methods according to the current disclosure have the advantage that the dielectric material is partially deposited using thermal deposition, thus reducing plasma exposure of the substrate.

### Master Cycle

The thermal deposition subcycle and the plasma deposition subcycle are each repeated for a predetermined number of times to complete a master deposition cycle (“master cycle”). For example, a master cycle in a deposition process may be performed from 1 to about 800 times, or from about 5 to about 800 times, or from about 10 to about 800 times, or from about 100 to about 800 times. In some embodiments, a master cycle is performed from about 3 to about 500 times, or from about 5 to about 500 times, or from about 10 to about 500 times, or from about 50 to about 500 times. In some embodiments, a master cycle is performed from about 50 to about 300 times, or from about 10 to about 200 times, or from about 50 to about 600 times. The number of repetitions of the master cycle depends on the per-cycle growth rate (gpc) of the dielectric material and of the desired thickness of the material.

In some embodiments, a deposition process according to the current disclosure comprises at least one subcycle that does not contain providing the catalyst into the reaction chamber. In some embodiments, the catalyst is provided separately from both the thermal deposition subcycle and the plasma deposition subcycle. In such embodiments, the process comprises a separate catalyst subcycle. The catalyst subcycle may comprise providing a catalyst into the reaction chamber and purging the reaction chamber. The catalyst subcycle may comprise providing a catalyst into the reaction chamber and not purging the reaction chamber. In some embodiments, metal or metalloid of the catalyst may be incorporated into the first material or the second material. The metal or metalloid content may be regulated by increasing the number of thermal or plasma deposition subcycles relative to the catalyst subcycle to reduce metal or metalloid incorporation, and vice versa. If the metal or metalloid of the catalyst is the same metal or metalloid deposited as the first or the second material, the catalyst subcycle may be merged with a thermal or plasma deposition subcycle.

### Activation Treatment

In some embodiments, the method further comprises an activation treatment before the dielectric material deposition, wherein the activation treatment comprises providing a catalyst to the reaction chamber in a vapor phase; and providing an oxygen precursor into the reaction chamber in a vapor phase. Thus, in some embodiments, the deposition process comprises an activation treatment before the initiation of the actual material growth. A catalyst subcycle used in some embodiments, may be a similar process. In some embodiments, the catalyst and the oxygen precursor are provided into the reaction chamber cyclically in the activation treatment. In some embodiments, the substrate may be exposed to the catalyst and to the oxygen precursor alternately and sequentially. In some embodiments, the activation treatment is performed directly before the deposition of the dielectric material is started. The activation treatment may be performed in the same deposition assembly in which the dielectric material is deposited. In some embodiments, the activation treatment is performed in the same multi-station deposition chamber in which the dielectric material is deposited. For example, DMAI and water may be provided cyclically, for example alternately and sequentially, into the reaction chamber in vapor phase, with 1 second pulse length for each reactant. In some embodiments, the catalyst pulse length during the activation treatment is from about 0.5 seconds to about 10 seconds, such as 1 second, 2 seconds or 6 seconds. In some embodiments, the first oxygen reactant pulse length during the activation treatment is from about 0.5 seconds to about 10 seconds, such as 1 second, 2 seconds or 6 seconds. The pressure during the activation treatment may be the same pressure used during the deposition of dielectric material. In some embodiments, the activation treatment is performed at a pressure of about 2 to 10 Torr, such as at a pressure of about 6 Torr or about 8 Torr.

The oxygen precursor used in the activation treatment may be the same oxygen precursor used in the thermal deposition subcycle. Alternatively, the oxygen precursor used in the activation treatment may be a different oxygen precursor than the one used in the thermal deposition subcycle. In some embodiments, one oxygen precursor (such as formic acid or water) is used in the activation treatment, and two oxygen precursors (such as formic acid and water) are used in the thermal deposition subcycle. Using an activation treatment before deposition may reduce the number of deposition cycles needed for depositing dielectric material of desired thickness. In some embodiments, the faster growth may be due to reduced delay in growth initiation. Without limiting the current disclosure to any specific theory, the deposition may be initiated in a more uniform manner throughout the first surface relative to deposition schemes without an activation treatment. This may have advantages especially in embodiments, in which thin dielectric material layers are sought after. A thin dielectric material layer may be, for example, less than 15 nm in thickness. For example, the thickness of a thin dielectric material layer may be from about 2 nm to about 10 nm, for example 3 nm, 5 nm, or 8 nm. An activation treatment may lead to earlier layer closure, therefore enabling the deposition of substantially or completely continuous layers having a lower thickness. Additionally, an activation treatment may lead to lower number of defects. Using an activation treatment may additionally allow for uniform deposition into narrow-pitch structures, such as structures comprises gaps having a width of 40 nm or less, or having a width of 30 nm or less, or having a width of 25 nm or less.

A plasma treatment may be used to activate the dielectric surface. For example, the silylated dielectric surface may be exposed to a H₂ plasma.

### Surface Pretreatments

In embodiments, a dielectric first surface may be selectively blocked relative to another surface, for example by selectively silylating the dielectric surface. In some embodiments, the dielectric surface is blocked by exposure to a silylation agent, such as alyltrimethylsilane (TMS-A), chlorotrimethylsilane (TMS-Cl), N-(trimenthylsilyl)imidazole (TMS-Im), octadecyltrichlorosilane (ODTCS), hexamethyldisilazane (HMDS), or N-(trimethylsilyl)dimethylamine (TMSDMA). In some embodiments, the dielectric blocking step may be omitted. In some embodiments, the blocking may aid in subsequent selective passivation of a metal surface, as described below. Thus, blocking a dielectric surface may, in some embodiments, allow the selective passivation of another surface, such as a metal surface or a dielectric surface of different composition. In some embodiments, the blocked dielectric surface may be treated, such as with a plasma, to provide the desired surface terminations to facilitate catalyst chemisorption, as described in more detail below. A second surface, such as a metal surface, is passivated, for example by selectively forming an organic polymer layer on the second surface. In some embodiments, the silylation of the dielectric surface aids in the selectivity of the formation of the polymer passivation layer (such as layer comprising polyimide or polyamic acid) on a second surface. In some embodiments, blocking, such as silylation, does not require a specific removal step before depositing dielectric material on the first surface.

Subsequently, a metal or metalloid catalyst is selectively deposited on the first dielectric surface relative to the second surface. In some embodiments, the catalyst is selectively chemisorbed on the dielectric surface. The catalyst may be, for example, a metal or metalloid catalyst as described below.

Dielectric material is then selectively deposited on the first surface relative to the passivated second surface by providing a silicon precursor into the reaction chamber. The catalyst may improve the interaction between the substrate and the silicon precursor leading to catalytic dielectric material growth selectively on the dielectric first surface of the substrate relative to the second surface (such as a passivated metal or metal oxide surface). The dielectric material may be deposited by a cyclical vapor deposition process in which the substrate is alternately contacted with the catalyst and the silicon precursor until a dielectric material of a desired thickness has been selectively deposited. Following dielectric material deposition, the passivation layer on the second surface may be removed, such as by etching. Etching may be performed, for example, by a plasma or a chemical treatment.

In some embodiments, a first dielectric surface, such as an oxide surface, on a substrate is blocked by silylation with a silylating agent such as alyltrimethylsilane (TMS-A), chlorotrimethylsilane (TMS-Cl), N-(trimenthylsilyl)imidazole (TMS-Im), octadecyltrichlorosilane (ODTCS), hexamethyldisilazane (HMDS), or N-(trimethylsilyl)dimethylamine (TMSDMA), an organic polymer is selectively deposited on a second surface of the same substrate, a metal or metalloid catalyst such as an aluminum catalyst is selectively deposited on the dielectric surface of the same substrate, and dielectric material is subsequently selectively deposited on the first surface of the substrate relative to the passivated second surface. For example, a dielectric material layer may be selectively deposited on a dielectric surface, such as a metal oxide surface, a silicon oxide surface or a low k surface, relative to an adjacent metal surface by, for example, blocking the first surface by silylation with a silylating agent, using a thiol SAM or polyimide layer to passivate the metal surface, using trimethyl aluminum (TMA), dimethylaluminumchloride, aluminum trichloride (AlCl₃), dimethylaluminum isopropoxide (DMAI), tris(tertbutyl)aluminum (TTBA), tris(isopropoxide)aluminum (TIPA), tris(dimethylamino) aluminum (TDMAA) or triethyl aluminum (TEA) as the catalyst, and a using a tetraethoxysilane as the silicon precursor. In some embodiments, the silylated dielectric surface is plasma-treated prior to providing the catalyst into the reaction chamber. The substrate may be contacted with a sufficient quantity of the blocking agent and for a sufficient period of time that the dielectric surface is selectively blocked with silicon species. In some embodiments, the dielectric surface is not passivated with a self-assembled monolayer (SAM).

In some embodiments, the process according to the current disclosure comprises providing a passivation agent into the reaction chamber in a vapor phase to selectively passivate the second surface before providing a catalyst into the reaction chamber. An organic polymer passivation layer may be selectively formed on the second (for example metal) surface relative to the first dielectric surface by providing a passivation agent into the reaction chamber. A passivation agent may be provided by a cyclic deposition process. For example, polyimide-comprising passivation layer may be deposited by providing an acetic anhydride and a diamine alternately and sequentially into a reaction chamber to form a passivation layer. The passivation layer may be selectively deposited on the second surface by providing a passivating agent into the reaction chamber. In some embodiments, the passivating layer on the metal or metallic surface inhibits, prevents or reduces the formation of the dielectric material on the metal or metallic surface.

### Temperature

In some embodiments, dielectric material may be deposited at a temperature from about 80° C. to about 400° C. The deposition of dielectric material may be performed at a substantially constant temperature. In such embodiments, the temperature may be, for example, from about 180° C. to about 300° C. In some embodiments, the thermal deposition subcycle and the plasma deposition subcycle are performed at different temperatures. The catalyst may be provided into the reaction chamber at the same temperature as at least one of the deposition subcycles is performed. Alternatively, the temperature during providing the catalyst into the reaction chamber is different from the temperature at which at least one of the deposition subcycles is performed. In some embodiments, the substrate is heated before providing the catalyst into the reaction chamber. In embodiments comprising depositing a passivation blocking layer and a passivation layer, the temperature for the deposition of said passivation layers may be independently selected. For example, a temperature during the silylation process may be from about 50° C. to about 500° C., or from about 100° C. to about 300° C. As another example, a polyimide-comprising passivation layer may be deposited at temperatures below 190° C., and subsequently heat-treated at a temperature of about 190° C. or higher (such as 200° C. or 210° C.) to increase the proportion of the organic material from polyamic acid to polyimide, and to improve the passivation properties of the passivation layer.

For example, in thermal deposition subcycle, dielectric material may be deposited at a temperature from about 200° C. to about 400° C., or at a temperature from about 250° C. to about 350° C., or at a temperature from about 300° C. to about 375° C. In plasma-enhanced deposition, the chemical reactions are promoted by reactive species in plasma. Therefore, lower temperatures compared to thermal (i.e. processes excluding plasma) may be used. In some embodiments, the plasma deposition subcycle according to the current disclosure is a plasma-enhanced ALD-type process. In some embodiments, the plasma deposition subcycle according to the current disclosure is a plasma-enhanced cyclic CVD-type process. In some embodiments, a plasma deposition subcycle is performed at a temperature from about 80° C. to about 400° C., such as at a temperature from about 100° C. to about 350° C. For example, dielectric material may be deposited at a temperature from about 100° C. to about 350° C., or at a temperature from about 100° C. to about 250° C., or at a temperature from about 100° C. to about 200° C. in the plasma deposition subcycle. In some embodiments, the plasma deposition subcycle according to the current disclosure may be performed at ambient temperature. In some embodiments, ambient temperature is room temperature (RT). In some embodiments, ambient temperature may vary between 20° C. and 30° C.

### Pressure

The methods according to the current disclosure may be performed in reduced pressure. In some embodiments, a pressure within the reaction chamber during the deposition process according to the current disclosure is less than 500 Torr, or a pressure within the reaction chamber during the deposition process is between 0.1 Torr and 500 Torr, or between 1 Torr and 100 Torr, or between 1 Torr and 20 Torr. In some embodiments, a pressure within the reaction chamber during the deposition process is less than about 10 Torr, less than 50 Torr, less than 100 Torr or less than 300 Torr.

A pressure in a reaction chamber may be selected independently for different process steps. In some embodiments, at least two different pressures are used during a deposition process according to the current disclosure. For example, a different pressure may be used for a thermal deposition subcycle than for a plasma deposition subcycle. A different pressure may be used for providing a catalyst into the reaction chamber than for a thermal deposition subcycle and plasma deposition subcycle. In some embodiments, the substantially whole deposition process is performed at a substantially constant pressure, for example in a pressure between about 2 Torr and about 9 Torr. In some embodiments, the catalyst is provided into the reaction chamber at a lower pressure than the thermal deposition subcycle and the plasma deposition subcycle.

In embodiments comprising an activation treatment, a different pressure may be used for an activation treatment than for the deposition steps (“activation pressure”). For example, in some embodiments, an activation pressure may be lower than about 10 Torr, lower than about 20 Torr or lower than about 50 Torr. In some embodiments, an activation pressure is lower than about 5 Torr, such as about 0.5 Torr, about 1 Torr, about 2 Torr or about 3 Torr.

In some embodiments, a pressure during a thermal deposition subcycle is lower than about 20 Torr, or lower than about 10 Torr. In some embodiments, a pressure during a thermal deposition subcycle is higher than about 1 Torr. In some embodiments, a pressure during a plasma deposition subcycle is lower than about 20 Torr. In some embodiments, a pressure during a plasma deposition subcycle is lower than about 10 Torr. In some embodiments, a pressure during a plasma deposition subcycle is higher than about 5 Torr. In some embodiments, a pressure during a plasma deposition subcycle is higher than about 10 Torr. In some embodiments, a pressure during a plasma deposition subcycle is between about 3 Torr and about 25 Torr. A pressure during a deposition process may affect the properties of the deposited material. Especially in plasma-based processed, pressure may be used to regulate the plasma energy, and may thus be a relevant factor in controlling plasma-induced damage to substrate structures and passivation layers. In some embodiments, the thermal deposition subcycle according to the current disclosure is performed in constant pressure. In some embodiments, the plasma deposition subcycle according to the current disclosure is performed in constant pressure. In some embodiments, different pressures may be used during providing different reactants into the deposition chamber.

In some embodiments, two pressures may be used during a thermal deposition subcycle. For example, a first thermal subcycle pressure may be used during providing the silicon or metal precursor into the reaction chamber, and a second thermal subcycle pressure is used when providing the oxygen precursor into the reaction chamber. In some embodiments, the first thermal subcycle pressure is lower than the second thermal subcycle pressure. In some embodiments, the thermal deposition subcycle is performed at a constant pressure.

In some embodiments, two different pressures are used during a plasma deposition subcycle. The first plasma deposition pressure is used when providing the silicon precursor or the metal precursor into the reaction chamber. The first plasma deposition pressure may be the same as the first thermal deposition pressure. The second plasma deposition pressure is used when providing the plasma into the reaction chamber. In some embodiments, the first plasma deposition pressure is lower than the second plasma deposition pressure. For example, in some embodiments, a first plasma deposition pressure may be lower than about 10 Torr or lower than about 20 Torr. In some embodiments, the first plasma deposition pressure is lower than about 5 Torr, such as about 0.5 Torr, about 1 Torr, about 2 Torr or about 3 Torr. In some embodiments, the second plasma deposition pressure is higher than or equal to about 5 Torr. In some embodiments, the second plasma deposition pressure is lower than or equal to about 20Torr, or lower than or equal to about 10 Torr. In some embodiments, a second plasma deposition pressure is between about 5 Torr and about 12 Torr.

### DRAWINGS

The disclosure is further explained by the following exemplary embodiments depicted in the drawings. The illustrations presented herein are not meant to be actual views of any particular material, structure, device or an apparatus, but are merely schematic representations to describe embodiments of the current disclosure. It will be appreciated that elements in the figures are illustrated for simplicity and clarity and have not necessarily been drawn to scale. For example, the dimensions of some of the elements in the figures may be exaggerated relative to other elements to help improve the understanding of illustrated embodiments of the present disclosure. The structures and devices depicted in the drawings may contain additional elements and details, which may be omitted for clarity.

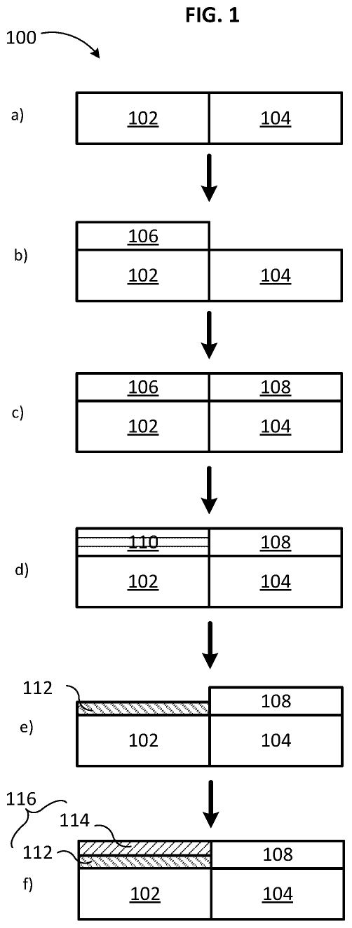

FIG. 1, panels a) to f) illustrates an embodiment of a method according to the current disclosure schematically. In the drawing, a substrate 100 comprising a first surface 102 and a second surface 104 is depicted. The first surface 102 is blocked relative to the second surface 104 by a blocking layer 106, the second surface 104 is selectively passivated by an organic passivation layer 108 relative to the first surface 102 comprising the blocking layer 106, followed by selective deposition of material comprising silicon and oxygen 112 on the first surface 102 relative to the passivated second surface 104.

Panel a) illustrates a substrate 100 having two surfaces 102, 104 having different material properties. For example, the first surface 102 may be a dielectric surface. The first surface 102 may comprise, consist essentially of, or consist of silicon oxide -based material or another dielectric material described in this disclosure. The second surface 104 may comprise, consist essentially of, or consist of a metal, such as copper (Cu).

Panel b) shows the substrate 100 of panel a) after selective blocking of the second surface 104, such as by silylation. For example, a blocking layer 106 may be formed selectively on a dielectric surface by exposing the substrate 100 to a silylating agent, such as alyltrimethylsilane (TMS-A), chlorotrimethylsilane (TMS-Cl), N-(trimenthylsilyl)imidazole (TMS-Im), octadecyltrichlorosilane (ODTCS), hexamethyldisilazane (HMDS), or N-(trimethylsilyl)dimethylamine (TMSDMA).

Panel c) shows the substrate 100 of panel b) after selective deposition of an organic passivation layer 108 on the second surface 104, such as by formation of a SAM or a polyimide-comprising layer.

Panel d) shows the substrate 100 of panel c) following selective deposition of a catalyst 110 on the first surface relative to the polymer passivation layer 108 on the second surface 104. The catalyst may be formed selectively on the first surface 102 by exposing the substrate to a catalyst such as trimethyl aluminum (TMA), dimethylaluminumchloride, aluminum trichloride (AlCl₃), dimethylaluminum isopropoxide (DMAI), tris(tertbutyl)aluminum (TTBA), tris(isopropoxide)aluminum (TIPA), tris(dimethylamino) aluminum (TDMAA) or triethyl aluminum (TEA). Although illustrated with an aluminum catalyst, in other embodiments catalysts comprising other metals may be used.

Panel e) shows the substrate 100 of panel d) following selective deposition of first material 112 on the catalyzed first surface 102 relative to the polymer passivated second surface 104. The first material 112 is deposited by a thermal deposition subcycle, for example by providing a silicon precursors comprising an alkoxy silane, such as tetraethoxysilane into the reaction chamber and providing an oxygen precursor, such as water, into the reaction chamber in accordance with the current disclosure. Without limiting the current disclosure to any specific theory, the alkoxy silane may decompose on the metal atoms on a catalyzed dielectric surface, leading to the deposition of first material comprising silicon and oxygen, such as silicon oxide-comprising material, on the first surface.

Panel f) shows the substrate of panel e) following selective deposition of second material 114 on the first surface 102 comprising the first material 112. The second material 114 is deposited by a plasma deposition subcycle, for example by providing a silicon precursor into the reaction chamber and providing a plasma, such as argon plasma into the reaction chamber. Dielectric material 116 according to the current disclosure is formed as a combination of depositing first material 112 and second material 114. In FIG. 1, the two materials are depicted as separate, but depending on the number of each of the subcycles, the materials may be partially or fully mixed. Each of the thermal deposition subcycle and the plasma deposition subcycle may be repeated to increase the thickness of the dielectric material 116. In the example, thermal deposition subcycle is performed before the plasma deposition subcycle. The two deposition subcycles may be performed in any order. However, in some embodiments, the advantages of combining thermal and plasma deposition subcycles may be more prominent when thermal deposition is performed as the first subcycle.

The layer thicknesses in FIG. 1 are arbitrary. The first material 112 thickness and the second material 114 thickness may be the same or different. Also, the thickness of the deposited dielectric material 116 relative to the passivation layer 108 thickness may vary.

After a sufficient amount of dielectric material is deposited, the passivation layer 108 may be removed from the second surface 104, such as by an etch process (not shown). In some embodiments, the etch process may comprise exposing the substrate 100 to a plasma. In some embodiments, the plasma may comprise oxygen atoms, oxygen radicals, oxygen plasma, or combinations thereof. In some embodiments, the plasma may comprise hydrogen atoms, hydrogen radicals, hydrogen plasma, or combinations thereof. In some embodiments, the plasma may comprise noble gas species, for example Ar or He species. In some embodiments, the plasma may consist essentially of noble gas species. In some embodiments, the plasma may comprise other species, for example nitrogen atoms, nitrogen radicals, nitrogen plasma, or combinations thereof. In some embodiments, the etch process may comprise exposing the substrate to an etchant comprising oxygen, for example O₃. In some embodiments, the substrate may be exposed to an etchant at a temperature of between about 30° C. and about 500° C., or between about 100° C. and about 400° C. In some embodiments, the etchant may be supplied in one continuous pulse or may be supplied in multiple pulses. The removal of the passivation layer 108 can be used to lift-off any remaining material comprising silicon and oxygen from over the metal layer, either in a complete removal of the passivation layer 108 or in a partial removal of the passivation layer 108 in a cyclical selective deposition and removal.

Any dielectric material from a thermal deposition subcycle or from a plasma deposition subcycle deposited on the second surface 104, such as on the polymer passivated metal layer 108, can be removed by a post-deposition treatment, such as an etch-back process. Because the dielectric material is deposited selectively on the first surface 102, any dielectric material 116 left on the passivation layer 108 will be thinner than the dielectric material deposited on the first surface 102. Accordingly, the post-deposition treatment can be controlled to remove all, or substantially all, of the deposited dielectric material 116 from over the second surface 104 without removing all of the dielectric material 116 from over the first surface. Repeated selective deposition and etching back in this manner can result in an increasing thickness of the dielectric material on the first surface 102 with each cycle of deposition and etch. Repeated selective deposition and etching back in this manner can also result in increased overall selectivity of the dielectric material 116 deposition on the first surface 102, as each cycle of deposition and etch leaves a clean passivation layer 108 over which the dielectric material is deposited at a lower rate compared to the first surface 102. In other embodiments, dielectric material over the second surface 104 may be removed during subsequent removal of the passivation layer 108.

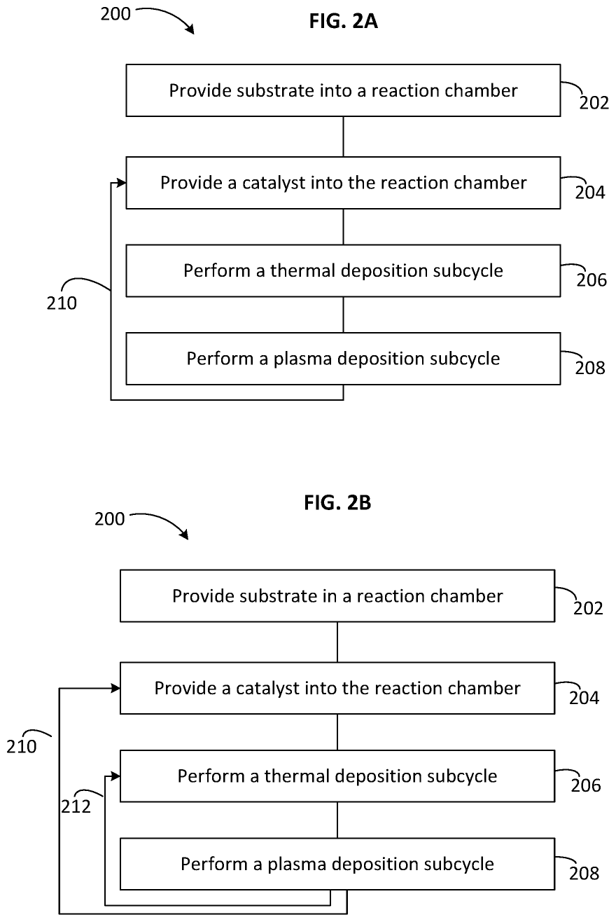

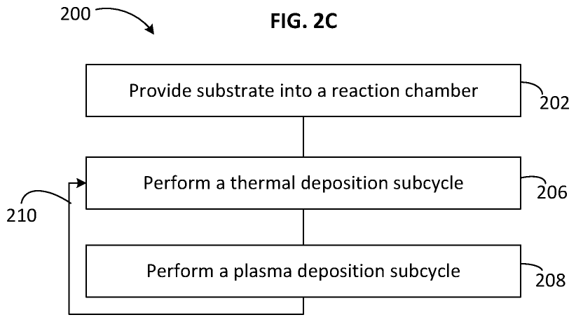

FIG. 2A is a block diagram of exemplary embodiments of a method according to the current disclosure. First, a substrate is provided in a reaction chamber at block 202. The substrate comprises a first surface and a second surface as described in the current disclosure. For example, the first surface may be a dielectric surface comprising a passivation blocking agent, such as a silylating agent, and the second surface may be a metal surface, such as copper surface, comprising an organic passivation layer. In an exemplary embodiment, the metal passivation layer comprises polyimide. The deposition of a passivation layer may comprise etching back the deposited passivation layer for improving the accuracy of subsequent selective deposition. The substrate may be heated at block 202 prior to providing a catalyst into the reaction chamber.

After providing the substrate into the reaction chamber, 202, a catalyst is provided into the reaction chamber at block 204 to contact the catalyst with the substrate. The catalyst may be, for example, an aluminum-comprising catalyst, such as dimethylaluminum isopropoxide. The catalyst is provided into the reaction chamber in vapor phase. The duration of providing the catalyst may be, for example from about 0.5 seconds to about 10 seconds, such as about 1 second, about 2 seconds, about 3 seconds, about 5 seconds or about 7 seconds. The reaction chamber may be purged after providing the catalyst into the reaction chamber. Purging is not indicated in FIG. 2A, but it may be optionally included in block 204.

At block 206, a thermal deposition subcycle is performed to deposit a first material on the first surface of the substrate. For example, a material comprising silicon and oxygen may be deposited in the thermal deposition subcycle. Thus, a silicon precursor comprising an alkoxy silane may be provided into the reaction chamber in a vapor phase. In an exemplary embodiment, the silicon precursor is tetraethoxysilane. The silicon precursor is selectively chemisorbed on the first surface relative to the second surface of the substrate. The silicon precursor may be provided into the reaction chamber (i.e. pulsed) for about 0.2 to 8 seconds, for example, about 0.5 seconds, about 1 second, about 3 seconds or about 5 seconds. In some embodiments, the silicon precursor is provided into the reaction chamber in multiple, such as 2, 4 or 10, consecutive pulses. In some embodiments, the silicon precursor is provided into the reaction chamber in a single pulse for each deposition cycle. The reaction chamber may be purged after a silicon precursor pulse. Purging is not indicated in FIG. 2A, but it may be optionally included in the thermal deposition subcycle of block 206.

In the thermal deposition subcycle, an oxygen precursor is provided into the reaction chamber in a vapor phase. In an exemplary embodiment, the oxygen precursor is water. The oxygen precursor reacts with the chemisorbed silicon precursor to form material comprising silicon and oxygen on the first surface of the substrate. The material comprising silicon and oxygen may comprise, for example, silicon oxide, and/or metal silicates, such as aluminum silicate. The reaction chamber may be purged after an oxygen precursor pulse. The deposition process according to the current disclosure is a cyclic deposition process, so providing the silicon precursor and the oxygen precursor may be repeated as many times as desired to obtain a sufficient amount of the first material on the substrate. As an alternative to material comprising silicon and oxygen, the first material may be a metal or metalloid oxide. For example, aluminum oxide may be deposited in a thermal deposition subcycle. In such embodiments, an aluminum precursor, such as DMAI, and an oxygen precursor, such as water, are provided into the reaction chamber.

If needed, an etch-back step may be performed after performing a predetermined number of thermal deposition subcycles. Further, if necessary, a passivation layer may be re-deposited after a predetermined number of thermal deposition subcycles.

After performing a predetermined number of thermal deposition subcycles, one or more plasma deposition subcycles 208 are performed. A plasma deposition subcycle may comprise providing a silicon or a metal precursor, depending on the targeted material, into the reaction chamber, and providing plasma, such as argon plasma, into the reaction chamber. The silicon and/or metal precursor may be the same precursor used in the thermal deposition subcycle. Alternatively, different precursors may be used. In the plasma deposition subcycle, the silicon, metal or metalloid precursor advantageously comprises oxygen to allow depositing an oxide material in the absence of additional oxygen sources.

In some embodiments, a material comprising a metal oxide, such as aluminum oxide is deposited in the plasma deposition subcycle.

In some embodiments, material comprising silicon and oxygen deposited in the plasma deposition subcycle comprises carbon. The plasma used in the deposition may be generated from a gas comprising argon and hydrogen. In some embodiments, the gas from which plasma is generated does not comprise oxygen, i.e. it is oxygen-free. In some embodiments, silicon oxycarbide films are deposited. The formula of the silicon oxycarbide films is generally referred to as SiOC for simplicity. As used herein, SiOC is not intended to limit, restrict, or define the bonding or chemical state, for example the oxidation state of any of Si, O, C and/or any other element in the film. Further, in some embodiments SiOC thin films may comprise one or more elements in addition to Si, 0 and C. In some embodiments the SiOC may comprise from about 0% to about 30% carbon on an atomic basis. In some embodiments the SiOC films may comprise from about 0% to about 70% oxygen on an atomic basis. In some embodiments the SiOC films may comprise about 0% to about 50% silicon on an atomic basis. When plasma is provided into the reaction chamber in the plasma deposition subcycle, reactive species may contact the substrate and may convert adsorbed silicon to SiOC on the dielectric surface. As discussed above, in some embodiments the plasma may comprise plasma generated from hydrogen, plasma generated from nitrogen, and/or plasma generated from a noble gas.

At loop 210, the deposition master cycle is initiated again. The deposition cycle may be repeated as many times as needed to deposit a desired amount of dielectric material on the substrate. In the embodiments of FIG. 2A, the master cycle is initiated by providing a catalyst into the reaction chamber. However, in some embodiments, it may not be necessary to provide catalyst at every master cycle, such as depicted in FIG. 2B. Conversely, in some embodiments, providing a catalyst into the reaction chamber may be performed during one or both deposition subcycles (not shown). Providing the catalyst frequently may affect the rate of deposition of the dielectric material positively. Additionally, addition of a catalyst may be used to tune the composition of the deposited dielectric material. In some embodiments, the deposition cycle may be performed from 2 to about 1,000 times, or from about 10 to about 500 times, or from about 10 to about 200 times, or from about 50 to 200 times. For example, the deposition cycle may be performed about 70 times, about 100 times, about 150 times, about 200 times or about 400 times. Although not depicted in the current disclosure, the process may comprise additional steps, for example refreshing any blocking or passivation that may be necessary for the continued selective deposition.

In some embodiments, the selective deposition of dielectric material on the first surface does not damage an organic passivation layer present on the second surface. Further, in some embodiments, the dielectric material is substantially not deposited on an organic passivation layer.

FIG. 2C is a block diagram of exemplary embodiments of a method according to the current disclosure in which the catalyst treatment is omitted. First, a substrate is provided in a reaction chamber at block 202 as above. After providing the substrate into the reaction chamber, 202, a thermal deposition subcycle 206 is performed to deposit a first material on the first surface of the substrate. For example, a material comprising silicon and oxygen may be deposited in the thermal deposition subcycle. The silicon precursor used in an embodiment without providing a catalyst into the reaction chamber may be more reactive than for embodiments in which a catalyst is used. In some embodiments, tetraacetoxysilane is used as a silicon precursor and water is used as an oxygen precursor.

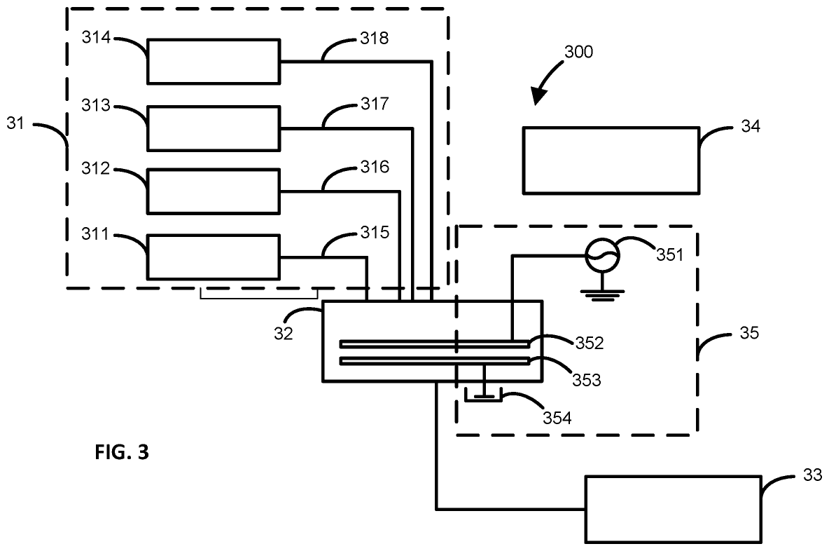

FIG. 3 illustrates a deposition assembly 300 according to the current disclosure in a schematic manner. In an aspect, a vapor deposition assembly 300 for selectively depositing dielectric material comprising silicon and oxygen on a first surface of a substrate relative to a second surface of the substrate is disclosed. The deposition assembly 300 comprises one or more reaction chambers 32 constructed and arranged to hold the substrate, a precursor injector system 31 constructed and arranged to provide a metal or metalloid catalyst, a silicon precursor and an oxygen precursor into the reaction chamber in a vapor phase and to provide plasma into the reaction chamber. The deposition assembly 300 further comprises a first reactant vessel 311 constructed and arranged to contain the catalyst, a second reactant vessel 312 constructed and arranged to contain the silicon precursor and a third reactant vessel 313 constructed and arranged to contain the oxygen precursor and a fourth reactant vessel 314 constructed and arranged to contain the plasma precursor. The assembly 300 is constructed and arranged to provide the catalyst, the silicon precursor and the oxygen precursor via the precursor injector system into the reaction chamber, and to generate plasma from the plasma precursor in the reaction chamber 32 for selectively depositing material comprising silicon and oxygen on the substrate.

In some embodiments, the vapor deposition assembly is further configured and arranged to provide a metal precursor into the reaction chamber to deposit a metal oxide or a metalloid oxide, such as boron oxide, on the first surface of the substrate. In such embodiments, the vapor deposition assembly 300 comprises a fifth reactant vessel for holding the metal precursor (not shown).

Deposition assembly 300 can be used to perform a method as described herein. In the illustrated example, deposition assembly 300 includes one or more reaction chambers 32, a precursor injector system 31, a first reactant vessel 311, a second reactant vessel 312, a third reactant vessel 313, a fourth reactant vessel 314, an exhaust source 33, and a controller 34. The deposition assembly 300 may comprise one or more additional gas sources (not shown), such as a plasma precursor source, an inert gas source, a carrier gas source and/or a purge gas source. In embodiments, in which blocking and/or passivation is performed in the same deposition assembly, the assembly may comprise the corresponding sources.

Reaction chamber 32 can include any suitable reaction chamber, such as an ALD or CVD reaction chamber as described herein. In some embodiments, the vapor deposition assembly comprises two chambers, or two deposition stations within one deposition chamber. One of the two chambers or deposition stations may be dedicated to performing a thermal deposition subcycle. The second chamber or deposition station may be dedicated to performing a plasma deposition subcycle. Depending on the relative lengths of the thermal deposition subcycle and the plasma deposition subcycle, there may be more than two deposition chambers or deposition stations in a chamber, and they may be allocated to different subcycles to optimize throughput.

The first reactant vessel 311 can include a vessel and a catalyst as described herein—alone or mixed with one or more carrier (e.g., inert) gases. A second reactant vessel 312 can include a vessel and a silicon precursor as described herein—alone or mixed with one or more carrier gases. A third reactant vessel 313 can include an oxygen precursor as described herein. For embodiments utilizing more than one oxygen precursors, there may be a corresponding number of third reactant vessels 313, although one is depicted in FIG. 3. Thus, although illustrated with four source vessels 311-314, deposition assembly 300 can include any suitable number of source vessels. Source vessels 311-314 can be coupled to reaction chamber 32 via lines 315-318, which can each include flow controllers, valves, heaters, and the like. In some embodiments, each of the catalyst in the first reactant vessel 311, the silicon precursor in the second reactant vessel 312, the oxygen precursor in the third reactant vessel 313 and the plasma precursor in the fourth reactant vessel 314 may be independently heated or kept at ambient temperature. In some embodiments, a vessel is heated so that a precursor or a reactant reaches a suitable temperature for vaporization.

Exhaust source 33 can include one or more vacuum pumps.

Controller 34 includes electronic circuitry and software to selectively operate valves, manifolds, heaters, pumps and other components included in the deposition assembly 300. Such circuitry and components operate to introduce precursors, reactants and purge gases from the respective sources. Controller 34 can control timing of gas pulse sequences, temperature of the substrate and/or reaction chamber 32, pressure within the reaction chamber 32, and various other operations to provide proper operation of the deposition assembly 300. Controller 34 can include control software to electrically or pneumatically control valves to control flow of precursors, reactants and purge gases into and out of the reaction chamber 32. Controller 34 can include modules such as a software or hardware component, which performs certain tasks. A module may be configured to reside on the addressable storage medium of the control system and be configured to execute one or more processes.

Other configurations of deposition assembly 300 are possible, including different numbers and kinds of precursor and reactant sources. For example, as described above, a reaction chamber 32 may comprise more than one, such as two or four, deposition stations. Such a multi-station configuration may have advantages if, for example, blocking, passivation and/or activation treatment are to be performed in the same chamber. Further, it will be appreciated that there are many arrangements of valves, conduits, precursor sources, and reactant sources that may be used to accomplish the goal of selectively and in coordinated manner feeding gases into reaction chamber 32. Further, as a schematic representation of a deposition assembly, many components have been omitted for simplicity of illustration, and such components may include, for example, various valves, manifolds, purifiers, heaters, containers, vents, and/or bypasses.

The vapor deposition assembly 300 comprises a plasma generation system 35 for generating the plasma used in the plasma deposition subcycle according to the current disclosure. The plasma generation system 35 may be provided with a RF power source 351 operably connected with the controller 34, and constructed and arranged to produce a plasma from the selected gas, such as argon, nitrogen, or a combination thereof.

The plasma-enhanced cyclic deposition process according to the current disclosure may be performed using the vapor deposition assembly 300. For example, a pair of electrically conductive flat-plate electrodes 352, 353 in parallel and facing each other in the interior (reaction zone) of the reaction chamber 32 may be provided, RF power (e.g., 13.56 MHz or 27 MHz) from a power source 351 may be provided to one side, and the other side may be electrically grounded 354, leading to excitation of a plasma between the electrodes 352, 353.

A substrate may be placed on the lower electrode 353, the lower electrode 353 thus serving as a susceptor. The lower electrode 353 may also comprise a temperature regulator, keeping a temperature of the substrate placed thereon relatively constant. The upper electrode 352 can serve as a shower plate, and precursor gases and optionally an inert gas(es) and/or purging gases can be introduced into the reaction chamber 32 through gas lines 314-316, respectively, and through the shower plate.

During operation of a deposition assembly 300, substrates, such as semiconductor wafers (not illustrated), are transferred into the reaction chamber 32. Once substrate(s) are transferred to reaction chamber 32, one or more gases from gas sources, such as precursors, carrier gases, and/or purge gases, are introduced into reaction chamber 32. Plasma is generated at suitable points in time to provide reactive species into the reaction chamber for performing the plasma deposition subcycle. During a thermal deposition subcycle, plasma is not used. A thermal deposition subcycle may be performed in a separate reaction chamber (not shown). By performing both subcycles appropriately, dielectric material is deposited on the first surface of the substrate.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Various modifications of the disclosure, in addition to those shown and described herein, such as alternative useful combinations of the elements described, may become apparent to those skilled in the art from the description. Such modifications and embodiments are also intended to fall within the scope of the appended claims.

1. A method of selectively depositing dielectric material on a first surface of a substrate relative to a second surface of the substrate by a cyclic deposition process, the method comprising
providing a substrate into a reaction chamber;
performing a thermal deposition subcycle to selectively deposit a first material on the first surface; and
performing a plasma deposition subcycle to selectively deposit a second material on the first surface,
wherein at least one of the first material and the second material comprises silicon and oxygen.

2. The method of claim 1, wherein a metal or metalloid catalyst is provided into the reaction chamber in a vapor phase before performing the thermal deposition subcycle.

3. The method of claim 1, wherein at least one of the thermal deposition subcycle and the plasma deposition subcycle are performed more than once before performing another subcycle.

4. The method of claim 1, wherein the last subcycle of the deposition process is a plasma deposition subcycle.

5. The method of claim 1, wherein the first material is a material comprising silicon and oxygen.

6. The method of claim 1, wherein the thermal deposition subcycle comprises
providing a silicon precursor comprising an alkoxy silane compound into the reaction chamber in a vapor phase; and
providing an oxygen precursor comprising oxygen and hydrogen into the reaction chamber in vapor phase to form first material comprising silicon and oxygen on the first surface.

7. The method of claim 1, wherein the second material is a material comprising silicon and oxygen.

8. The method of claim 1, wherein the plasma deposition subcycle comprises providing a silicon precursor comprising an alkoxy silane compound into the reaction chamber in a vapor phase; and
providing a plasma into the reaction chamber to form a reactive species for forming a second material comprising silicon and oxygen on the first surface.

9. The method of claim 1, wherein the first material and the second material are materials comprising silicon and oxygen.

10. The method of claim 1, wherein the first surface is a dielectric surface.

11. The method of claim 10, wherein the dielectric surface comprises silicon.

12. The method of claim 1, wherein the second surface comprises a passivation layer.

13. The method of claim 12, wherein the passivation layer comprises an organic polymer or a self-assembled monolayer (SAM).

14. The method of claim 2, wherein the catalyst is a metal halide, organometallic compound or metalorganic compound.

15. The method of claim 14, wherein the catalyst comprises trimethyl aluminum (TMA), dimethylaluminumchloride, aluminum trichloride (AlCl₃), dimethylaluminum isopropoxide (DMAI), tris(tertbutyl)aluminum (TTBA), tris(isopropoxide)aluminum (TIPA), tris(dimethylamino) aluminum (TDMAA) or triethyl aluminum (TEA).

16. The method of claim 6, wherein the alkoxy silane is selected from a group consisting of tetraacetoxysilane, tetramethoxysilane, tetraethoxysilane, trimethoxysilane, triethoxysilane and trimethoxy(3-methoxypropyl)silane.

17. The method of claim 6, wherein the oxygen precursor is water.

18. The method of claim 1, wherein a plasma used in the plasma deposition subcycle is generated from a noble gas.

19. The method of claim 1, wherein plasma ion energy of plasma used in the plasma deposition subcycle does not exceed 160 eV.

20. The method of claim 1, wherein at least two different pressures are used during a deposition cycle.

21. The method of claim 2, wherein a first pressure is used during providing the catalyst into the reaction chamber, and a second pressure is used during deposition subcycles.

22. The method of claim 21, wherein the first pressure is lower than the second pressure.

23. The method of claim 1, further comprising an activation treatment before the silicon-comprising material deposition, wherein the activation treatment comprises providing a catalyst into the reaction chamber in a vapor phase; and providing an oxygen precursor into the reaction chamber in a vapor phase.

24. The method of claim 23, wherein the catalyst and the oxygen precursor are provided into the reaction chamber cyclically.
